(19) United States
(12) Patent Application Publication
(10) Pub. No.: US 2002/0056501 A1
(43) Pub. Date: May 16, 2002

(54) Method, system, and computer program product for determining the loading on poles

(76) Inventors: Nelson G. Bingel, III, Orchard Park, NY (US); Lawrence J. Geitner, Hamburg, NY (US)

Correspondence Address: John M. Del Vecchio, Hodgson Russ LLP, Suite 2000, One M&T Plaza, Buffalo, NY, 14203-2391, US

(21) Appl. No.: 09/812,152

(22) Filed: Mar. 19, 2001

Related U.S. Application Data
(60) Provisional application No. 60/190,155, filed on Mar. 17, 2000.

(51) Int. Cl. G01R 21/00

(52) U.S. Cl. 156/64

(57) ABSTRACT

In a computer having a display device, an entry device, and a computer processor for executing a computer program, a method of pole analysis comprising the steps of: providing a computer executable program; running the computer executable program on the computer processor; inputting data pertaining to pole loading into the computer; determining the loading on the pole; and outputting the results. A computer system for determining loads on a pole, the system comprising a computer processor; computer executable instructions for being run on the computer processor; a computerized memory for storing pole data; computer executable instructions for determining pole loading; a means for outputting the results. A computer program product for determining the loading on a pole.

### CROSS REFERENCE TO A RELATED APPLICATION

Applicants hereby claim priority based on Provisional Application No. 60/190,155 filed Mar. 17, 2000 and entitled “Software for Calculating Utility Pole Loads” which is incorporated herein by reference.

### BACKGROUND

Utility poles are routinely relied upon to carry and support cables, lights, transformers, guy wires, conductors, equipment, and the associated ice and wind loads. However, due to ever increasing demands, poles are being subjected to ever increasing loading. For example, communications companies are eager to string new communication and fiber optic cables on existing poles. However, since the existing poles are already carrying loads, analyses need to be conducted to determine if the poles can safely handle any additional loading.

The same problems are encountered for determining the loading on poles constructed of other materials, for example, concrete, metal, and composites.

To date, the process of accessing the loading on a pole is an arduous task, due to many loading variables and rather lengthy calculations. Thus, the problem of determining pole loading is often left to engineers to solve. This, however, is costly, slow, inefficient, and sometimes prone to error.

### SUMMARY

The method, system, and computer program product described herein allow the loading on a pole to be determined quicker and more reliably than in the past. The methodology allows for a complete pole loading assessment, calculated from input pole loading data. A computer is provided for executing a computer software program that causes a computer to process pole loading data inputs, and to calculate the transverse and vertical loading on the pole. The user inputs the pole loading data from loads imposed from the pole itself, conductors and cables, transformers, equipment, guy wires, wind, and ice. Portions of this data may be retrieved from databanks where it is stored. The user then need only select the appropriate options from the graphical user interface screen displays, and view the pole loading summary report generated by the software program being executed on the computer. The output results may be in may be in summary report, table, chart, and graph type formats. The data for the pole loading may also be edited at any time, that is loads may be added or removed from the pole, and the pole loading summary report is automatically updated in real time.

The method, system, and computer program product provide an quick reliable way to determine the loading on a pole. The computer system has a computer processor, a computer software program having a plurality of computer executable instructions for being executed on the computer processor, an entry device for the input of data pertaining to pole loading, a memory for storing input data, and an output device for outputting the results generated when the computer executable instructions calculate the pole loading from the input data. The computer executable instructions also cause the computer to generate and display a plurality of output screen displays that may be in the form of tables, charts, and graphs. A summary report may also be printed, showing pole loading data the user input, and showing the output results calculated by the computer software program from the input data.

The invention herein also provides a method of pole loading analysis comprising the steps of: providing a computer executable program; running the computer executable program on a computer processor; inputting data pertaining to pole loading into the computer; determining the loading on the pole; outputting the results to a output means; and displaying the output results on screen displays in the form of tables, graphs, and charts. Updating the input data in real time may be another step in the methodology of the present invention.

Further, a computer program product for determining the loading on a pole is provided for herein, and comprises the computer executable instructions for determining the loading on the pole embodied in a CD-ROM (compact disk that functions as a read only memory), floppy disk, optical disk and the like.

### FIGURES

FIG. 1 shows the overall architecture for the system and methodology for determining the loading on a pole.

FIGS. 2-47 show the flow of an analysis for determining the loading on a pole.

FIGS. 48-63, 65-80, and 82-102 show the screen displays caused to be generated by the computer software program when the program is executed on a computer processor.

FIGS. 64, 81, 103-106 are flowcharts showing the operation of the software of the present invention.

### DESCRIPTION

Definitions

Effective Remaining Pole Strength—After a wood pole has been chipped (that is all decayed wood is removed up to six feet above the groundline), the final pole circumference is the effective circumference for the pole. The effective circumference considers all the decay conditions for a pole at a specific cross section and equates the remaining strength to the circumference of a smaller sound pole.

Effective Circumference—For a decayed pole, the effective circumference equates its remaining strength to the circumference of a completely sound, but smaller pole. Both external and internal decay are evaluated.

Groundline—Groundline (or ground line or GL) is a line that lies in the plane that intersects substantially perpendicularly the pole, at the point where the pole protrudes substantially vertically from the ground.

Pole—The term pole includes poles made from wood, concrete, composites, steel, metals, fiberglass, and other materials well known to those of ordinary skill in the art.

The method, computer program product, article of manufacture, and system of the invention will first be described, followed thereafter with a more detailed description.

The invention provides a new system, methodology, and computer program product for analyzing pole loading, and for organizing and storing data pertaining to pole specifications and pole loading in databanks. It is noted that the methodology, system, and computer program product herein are applicable to wood poles, metal poles, concrete poles, composite poles, steel poles, and other types of poles well known to those of ordinary skill in the art.

The loading on the pole comes from a variety of sources such as cables, equipment, wind, and transformers. A computer is provided for executing the computer software program. Data pertaining to pole loading is input into the computer, and the software program causes the computer processor to calculate pole loading from the input data, and also causes the computer to output the results to screen displays, printed media, graphically, or to other output devices well known to those of ordinary skill in the art.

The invention may be embodied and described in a variety of different contexts. For example, it may be embodied and described as any of the following; a methodology; a system; a computer program product; and an article of manufacture.

It is noted at this point that the mathematical formulas and calculations utilized in the computer software program for determining the bending moments and vertical stresses on poles under load are well known to those of ordinary skill in the art. Additionally, a number of formulas to perform such calculations are provided for in this description. For example, vertical stress at groundline for a pole, in pounds per square inch, is the vertical weight of the pole above ground multiplied by the overload capacity factor (safety factor), divided by the cross sectional area of the pole at the groundline, in pounds per square inch.

Method

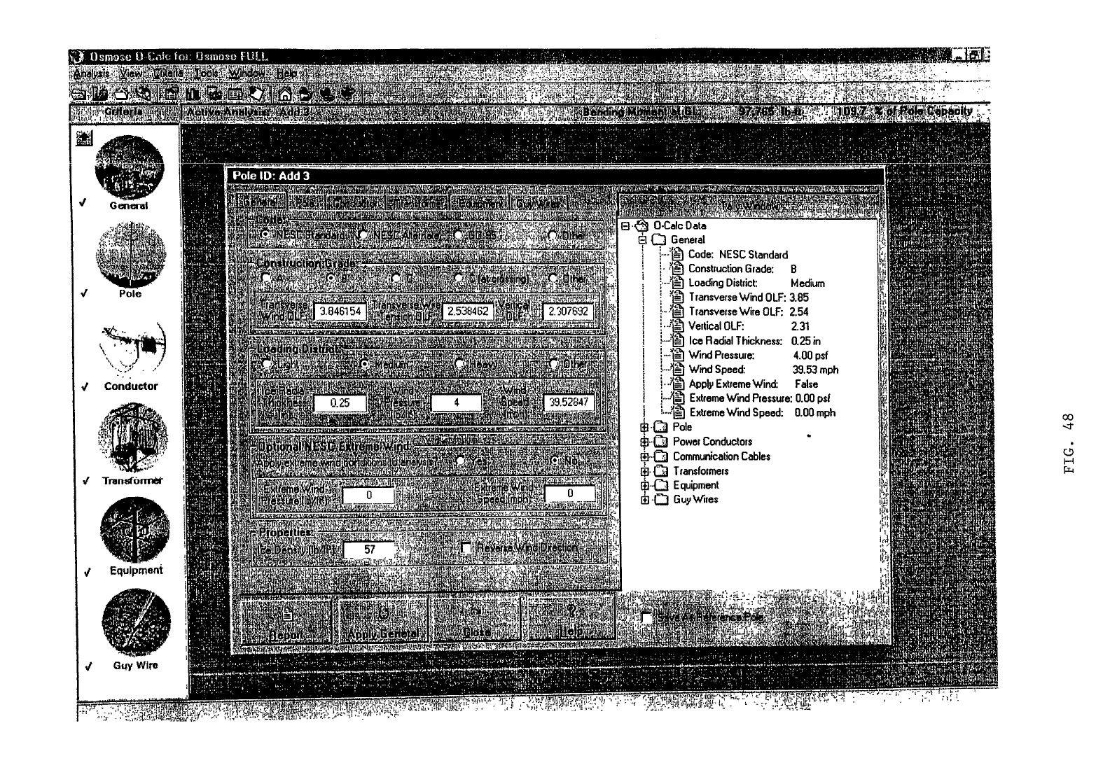

The methodology herein for determining the loading on a pole calls for a computer processor, an entry device for inputting data, computer executable instructions (a computer program) for being executed on the computer, and an output device for outputting the results of the executed program a display device. The method comprises the steps of: providing a computer, providing a computer executable program (the operational flow of the program seen in FIGS. 1, 64, 81, and 103-106); executing the computer executable program on a computer; inputting data pertaining to pole loading into the computer (data input screen displays seen in FIGS. 48, 65, 66, 72, 74, and 76); the computer for determining the loading on the pole from calculations made from the input data; and outputting the results to an output means. The methodology further comprises the step of selecting pole loading code standards for the pole loading analysis, these standards may be selected from a database having the pole loading code standards stored therein (FIG. 48). The computer executable program automatically causes the pole loading determinations to updated to be updated when data is input into the computer.

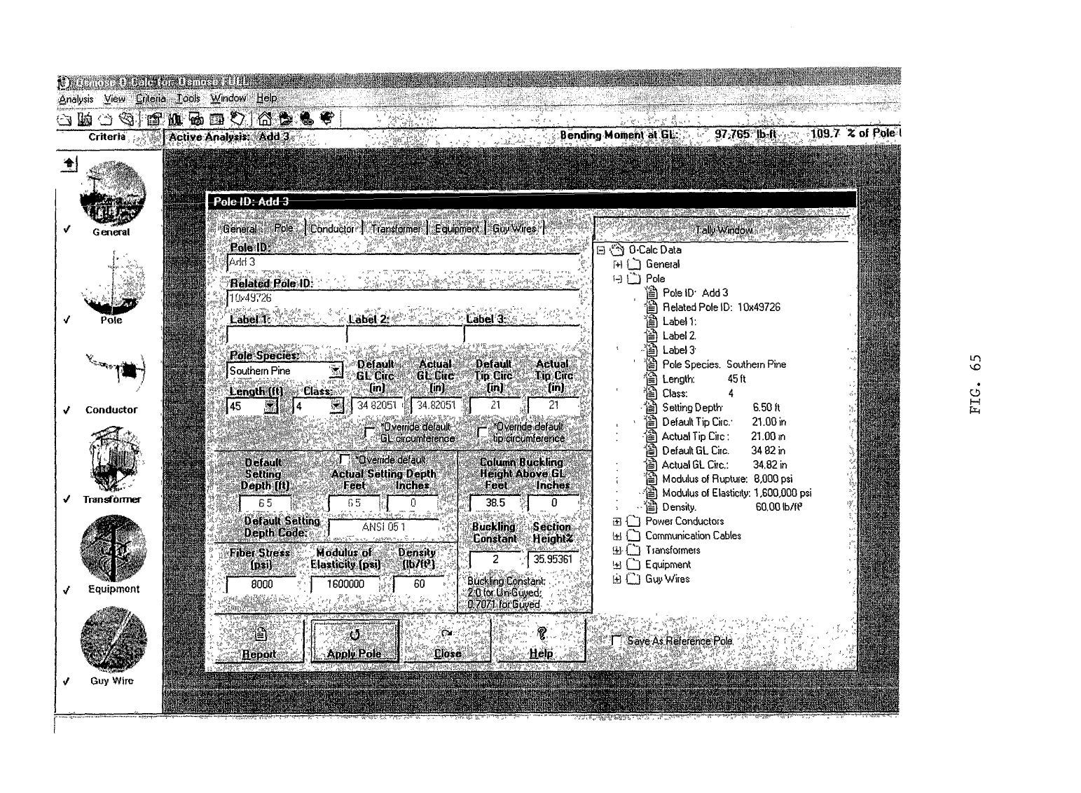

The input pole loading data includes loads placed on the pole from at least one of the following: power conductors; communications cables; fiber optic cables; the pole itself; transformers; equipment; guy wires; ice and wind (FIGS. 65, 66, 72, 74, and 76).

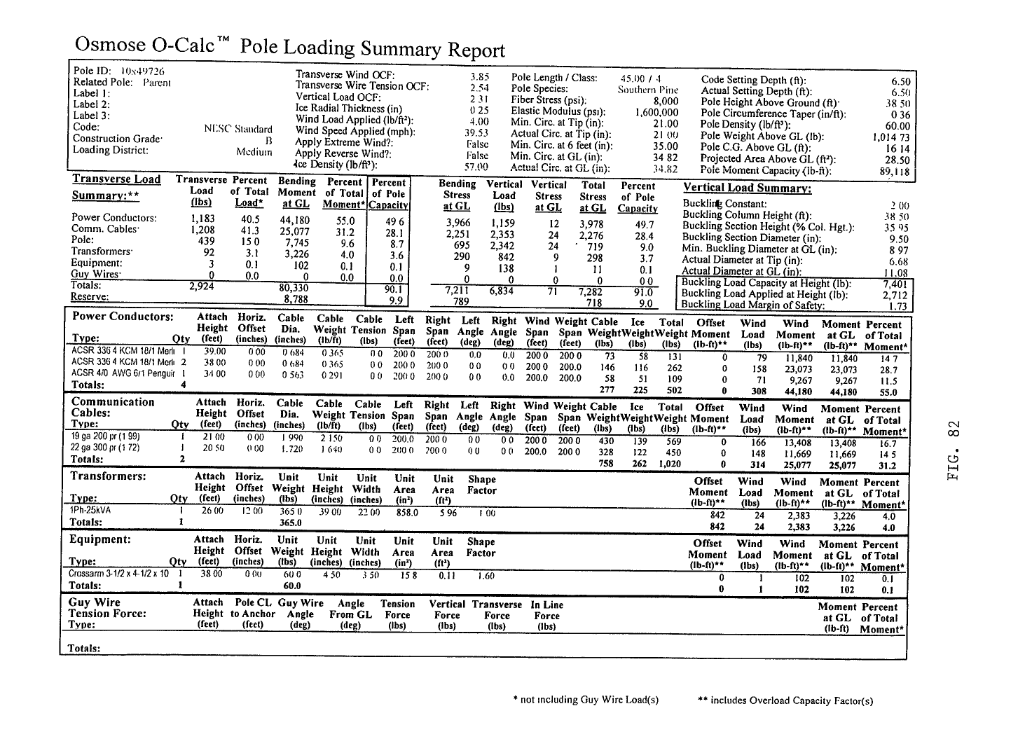

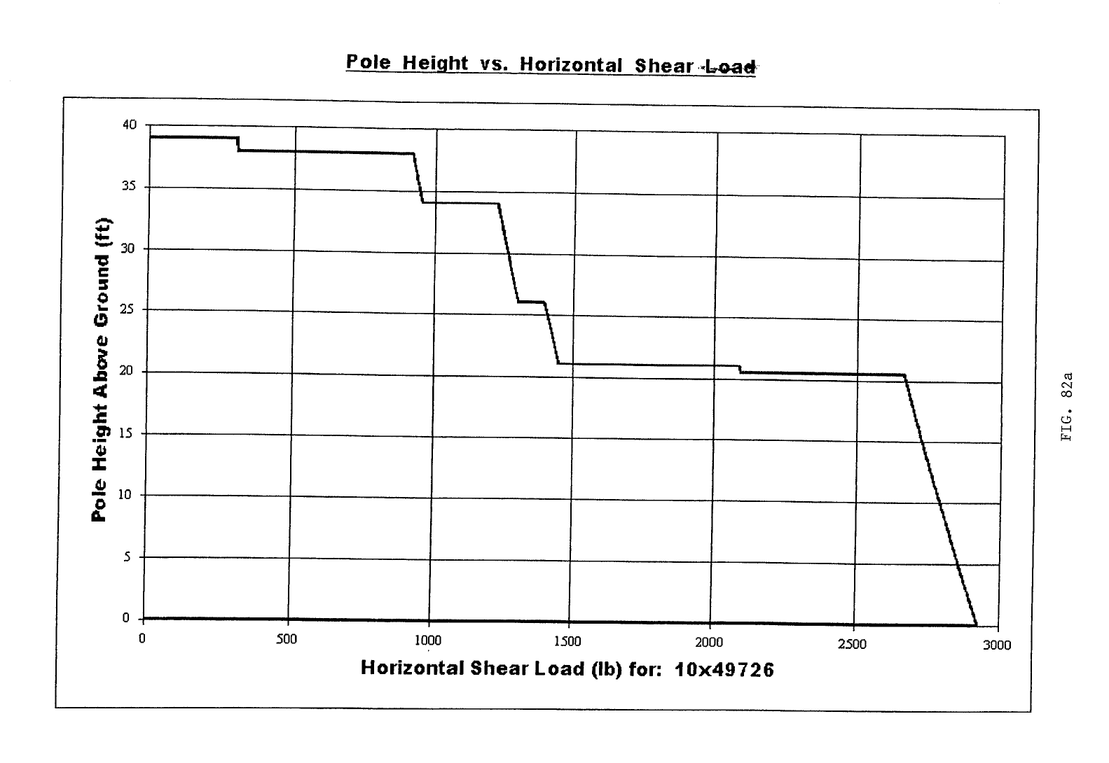

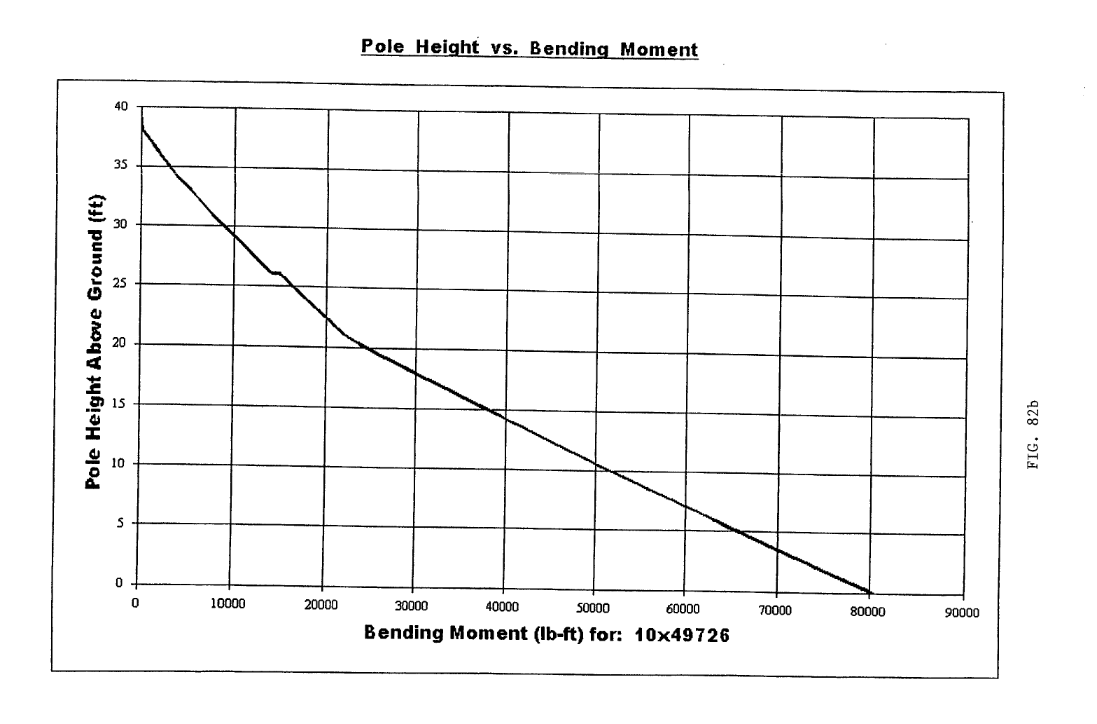

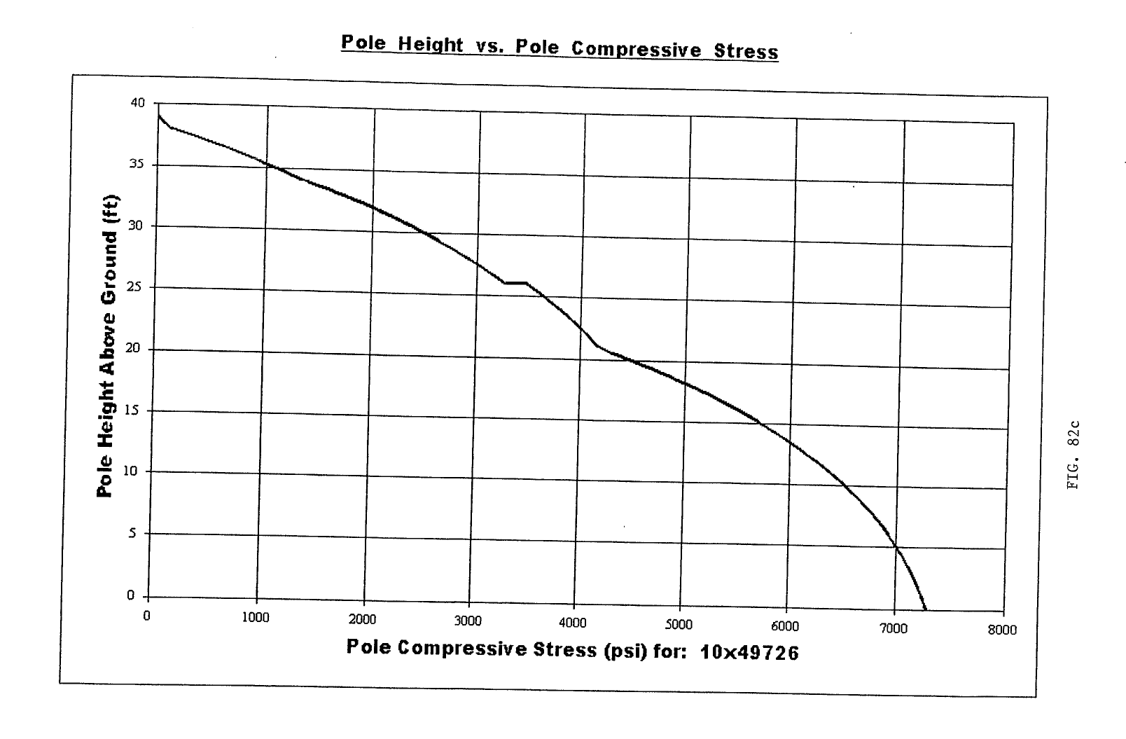

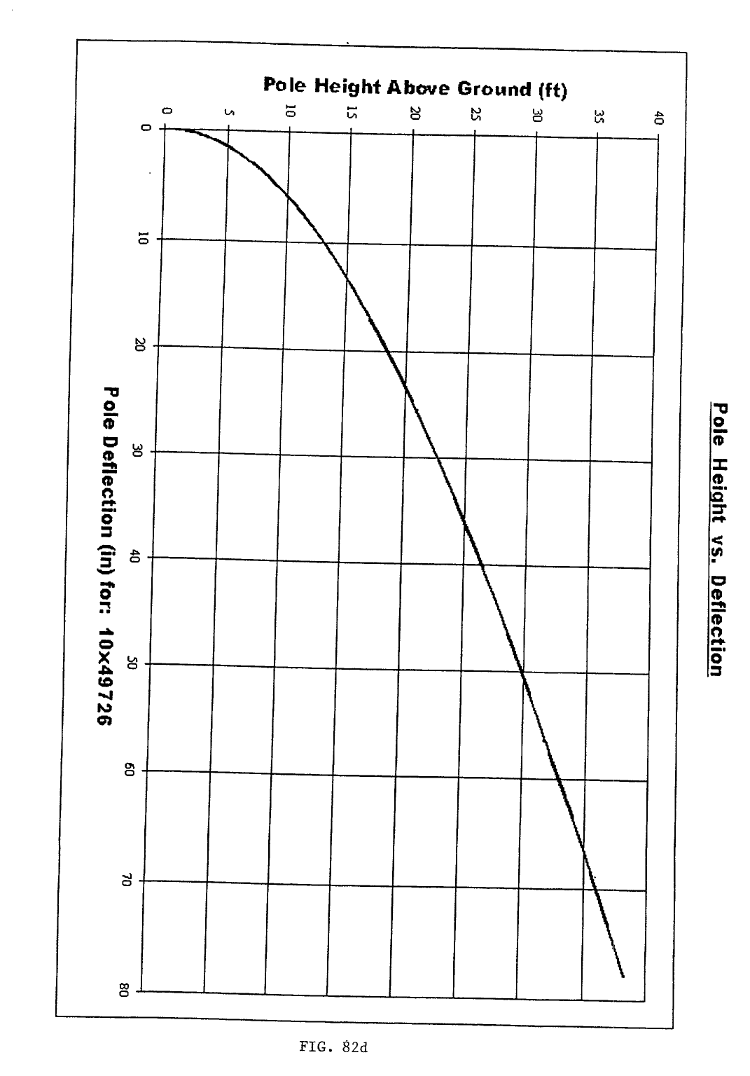

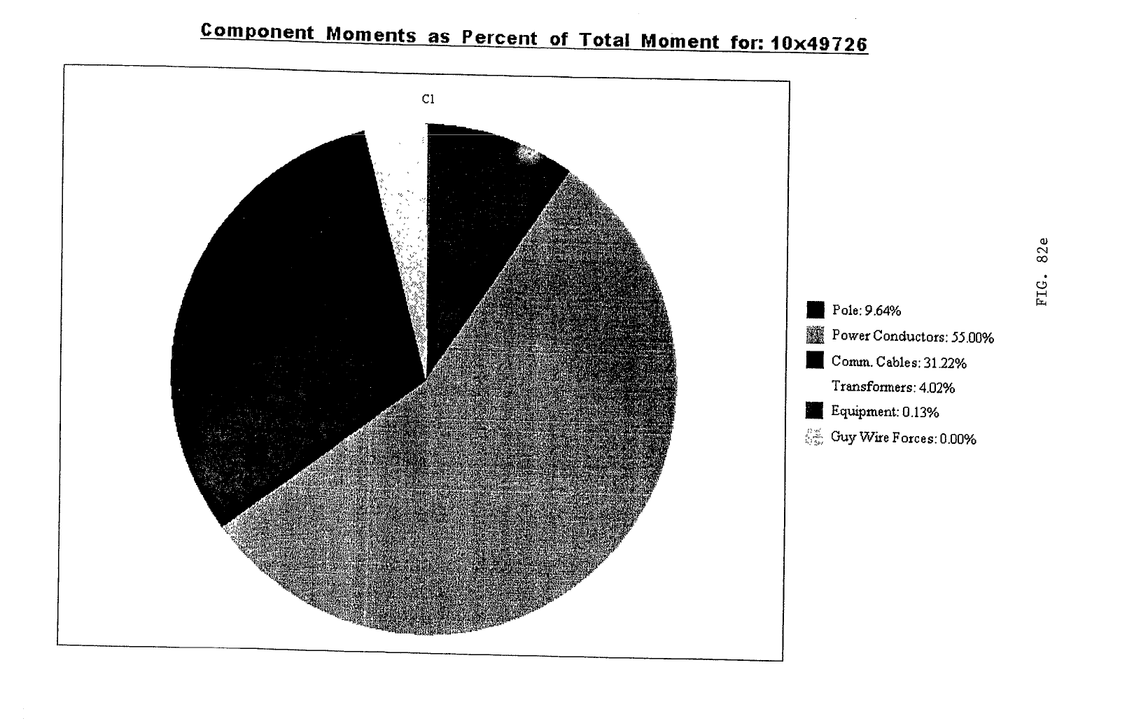

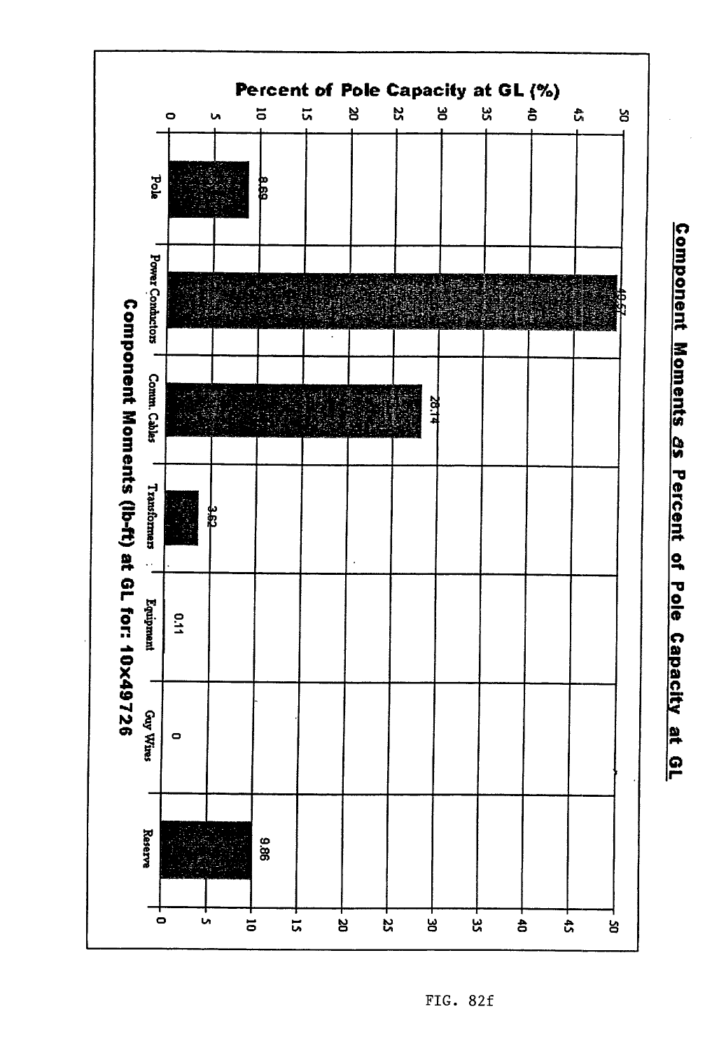

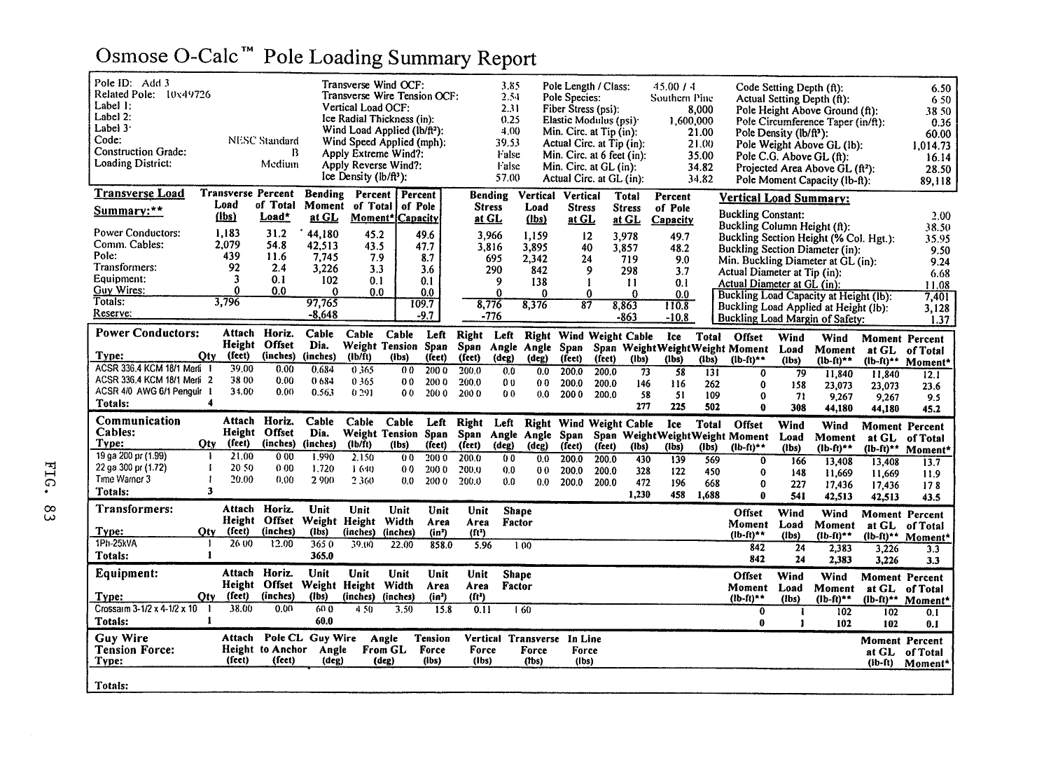

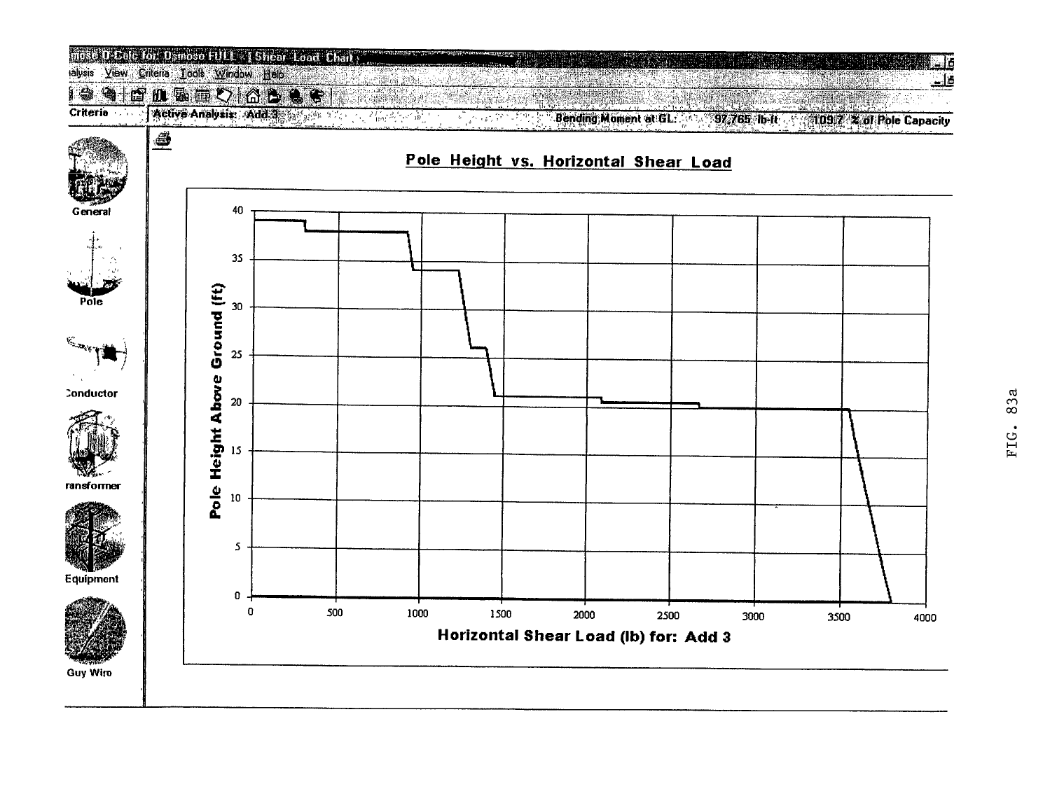

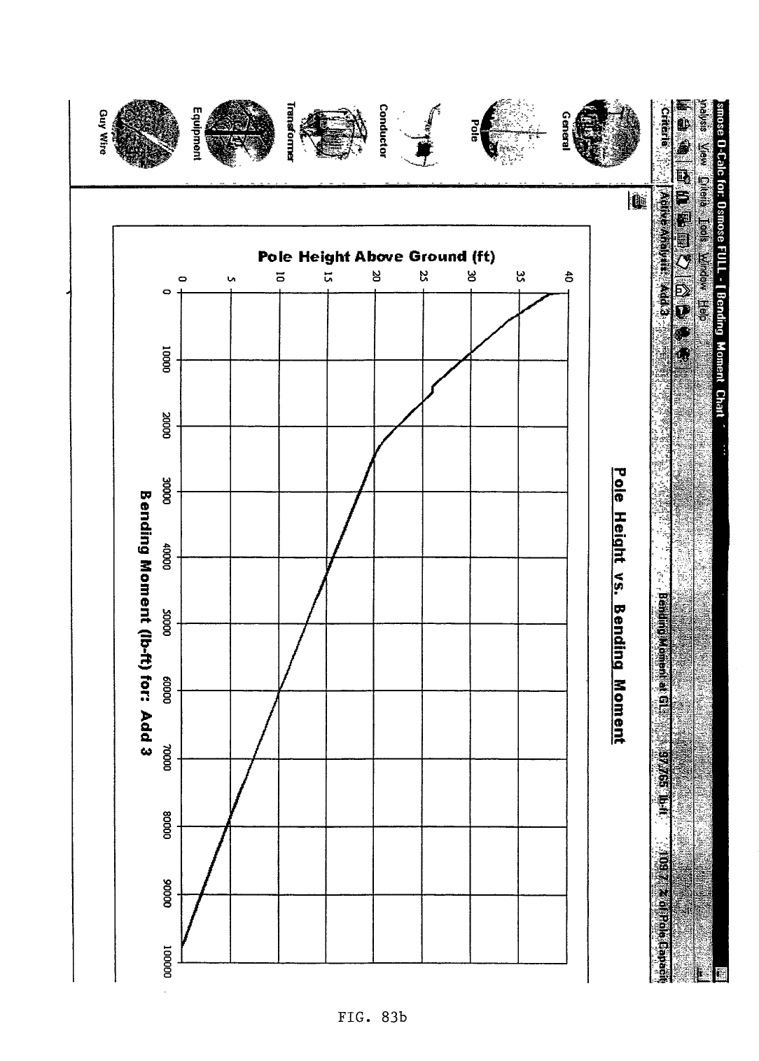

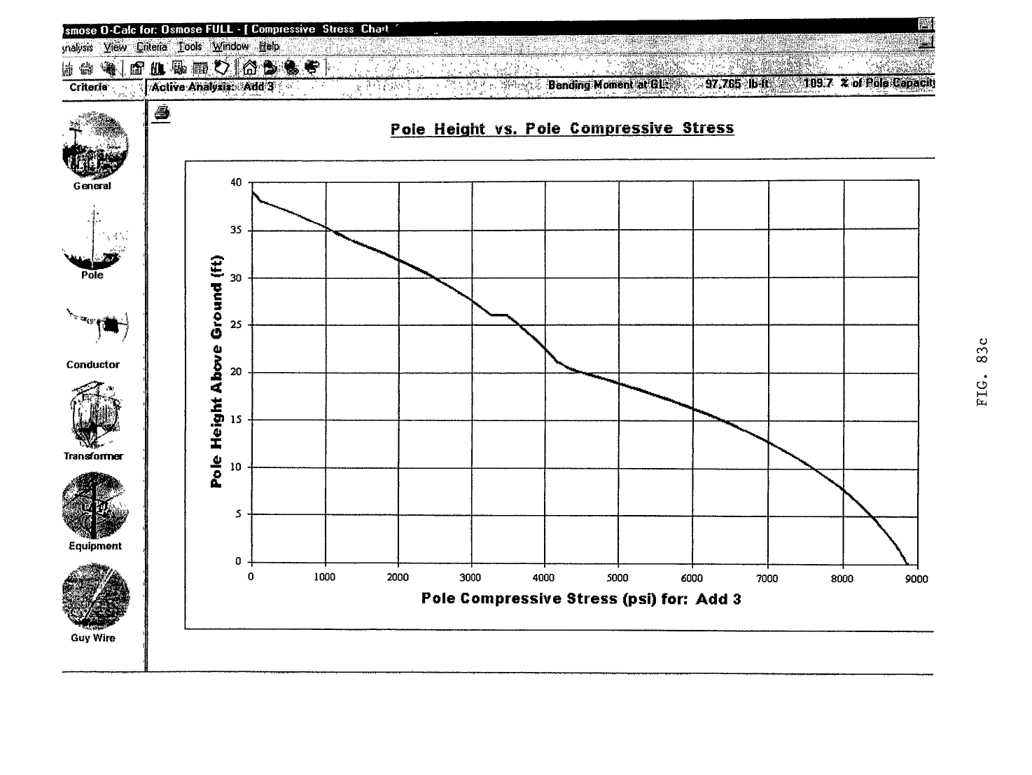

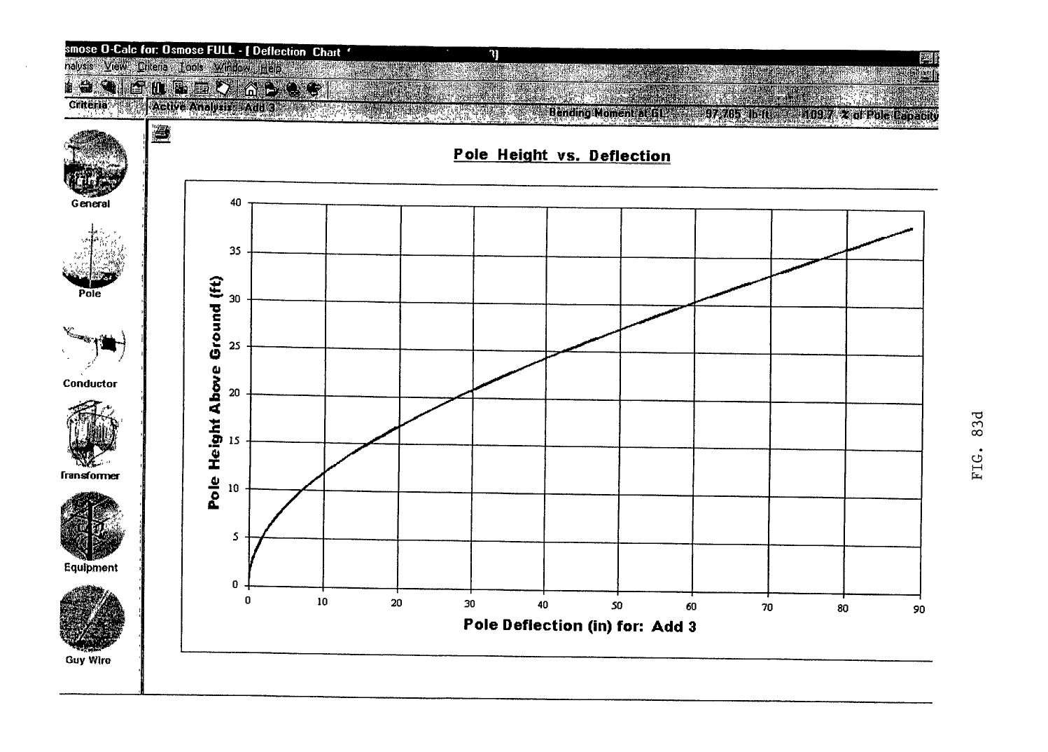

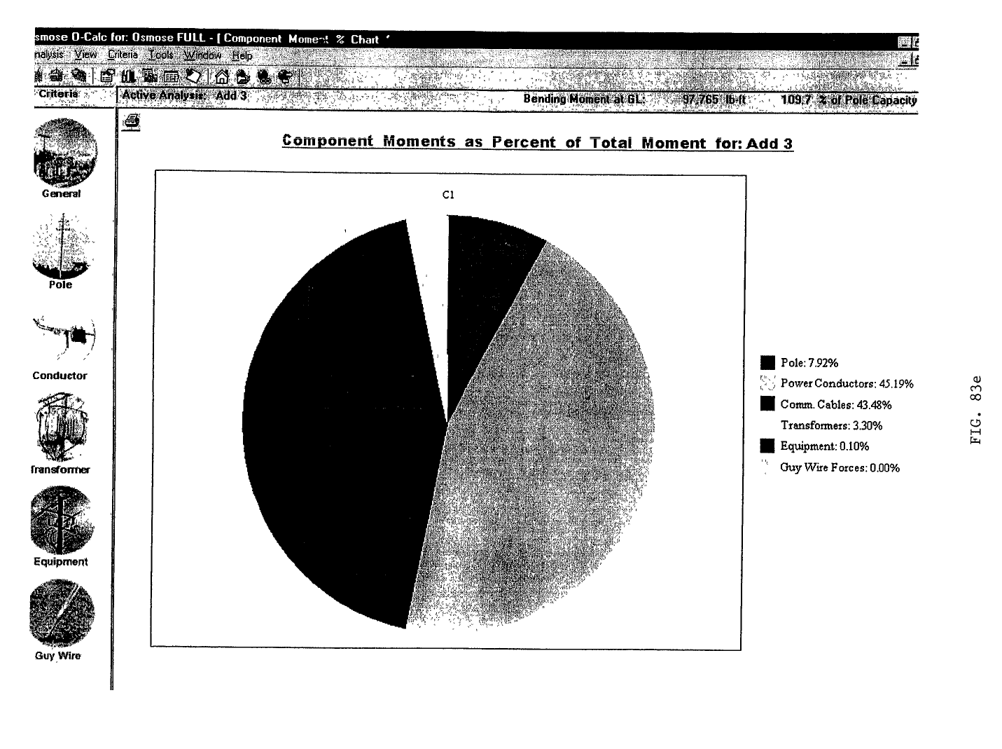

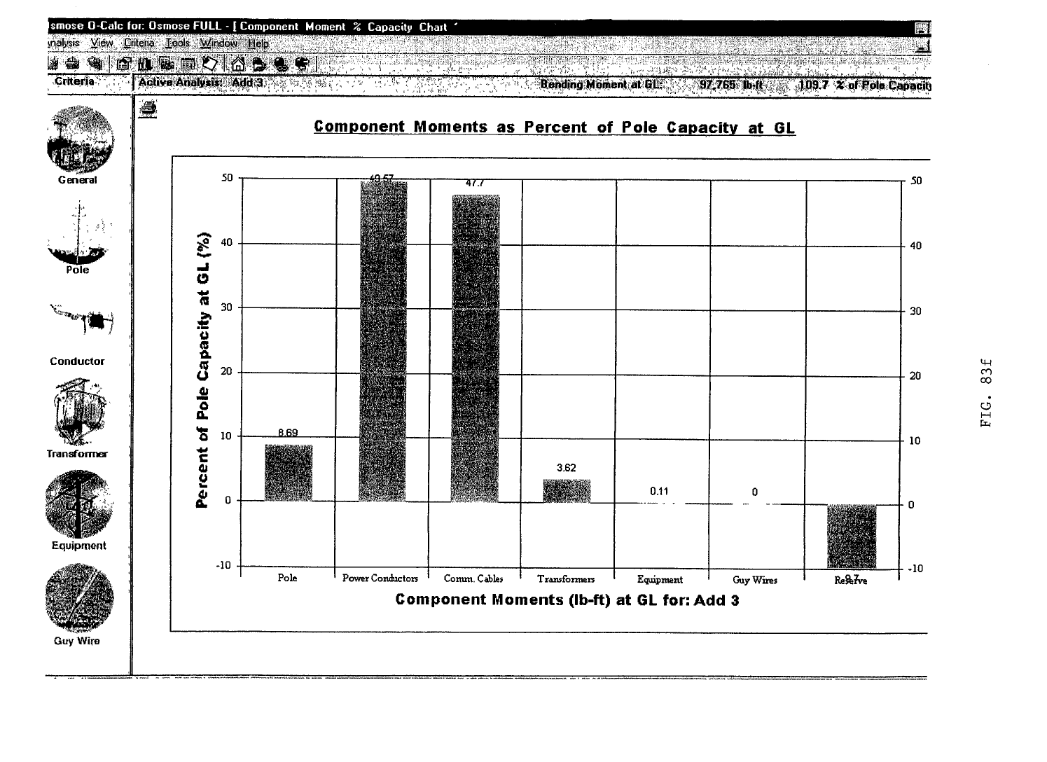

The computer executable instructions used in the method also determine the transverse loading on the pole and vertical loading on the pole caused by the loading imposed from the input data. In both cases the percentage of the pole capacity used by the loading and the percentage of pole capacity remaining are calculated, this is shown in the charts in FIGS. 82 and 83.

The step of inputting data pertaining to pole loading, is accomplished by way of inputting data into a plurality of data input pages. These data input pages are caused to be displayed on the computer when the computer executable program is being run on the computer. These data input pages include: a general data input page; a pole data input page; a conductor data input page; a transformer data input page; an equipment data input page; and a guy wire data input page (as shown in FIGS. 48, 65, 66, 72, 74, 76, respectively). Data may be manually input in these data pages by way of data input boxes, data input fields, and other ways well known to those skilled in the art. The user may access any of these pages while inputting data, so as to be able to go back and alter or modify past data inputs.

The method also calls for providing a tally window (see, for example, FIG. 48) having pull down menus for allowing the user to have access to the inputted data for each data input page, and for allowing the user access to the other data input pages. The method further calls for providing a real time tally calculations and updates in real time, a running tally of the bending moment on the pole at groundline and the percentage of pole capacity being utilized at that point in time. In FIG. 48, for example, the bending moment is 97,765 ft.-lb., and this uses 109.7% of the pole capacity. Of course, such a result as this wherein over 100% of the pole capacity is used alerts the user that the pole is overloaded.

The method also may also be embodied to include a the operation of performing a computerized logic check, for alerting the user to potential logical errors in inputted data, so that the error may be corrected before the analysis continues. For example, data is input that places a conductor 50 feet above the tip of a pole. Further, the methodology may be embodied to have a step in which the user may create reference poles (poles that serve as default configurations for poles having the same specifications, said feature seen in FIG. 48).

Additionally, the methodology provides a step wherein the user may conduct a “what if” scenario, for allowing the user to save the data for an existing pole, and then clone this data and create a cloned pole, and then changing the loading on the cloned pole, without the existing pole's data being altered. The user can then draw conclusions from the “what if” scenario results.

The method may be embodied to include the step of allowing the user to select the format of output results, for example, the output results may be in the form of a printed summary report (FIGS. 82 and 83); an electronic report; a screen display; an email. The results may be graphically output in at least one of the following forms: pole height versus horizontal shear load as a line graph, pole height versus bending moment as a line graph, pole height versus compressive stress as a line graph, component moment as percentage of total moment as a pie chart, component moment as percentage of pole capacity as a pie chart, pole height versus pole deflection as a line graph, as shown in FIGS. 82a-82f, and 83a-83f.

Computer Program Product

The invention further provides for a computer software program product that may be embodied in a computer usable medium. The computer program product is for being executed on a computer processor.

The computer usable medium has computer readable program codes embodied therein, the computer readable codes are for causing the computer to: define data input fields for the input of pole data; define data input fields for the input of pole loading data; determine the resultant pole loading values from the inputted pole data and the inputted pole loading data; and to display the results generated.

The computer program product further defines additional fields for the input of pole loading data, for example, data input fields for: conductor loading data, cable loading data, transformer loading data, transformer loading data, equipment loading data, guy wire loading data, ice loading data, wind loading data, and pole species data. The computer program also causes the computer to generate at least one of the following: a tally window of the loading on the pole; a real time display of the bending moment on the pole due to the loading; a warning logic procedure; a related pole analysis procedure; a reference pole analysis procedure; a loading summary report output; and graphical screen display outputs.

The computer program product may be embodied in the forms including CD-ROM (compact disk that functions as a read only memory), floppy disk, hard drive, and optical disk.

Article of Manufacture

The present invention may also be embodied as an article of manufacture having a computer usable medium having computer readable codes embodied therein, the codes for causing the computer to: define fields for the input of pole data; define fields for the input of pole loading data; determine the pole loading values from the inputted pole data and the inputted pole loading data; conduct a related analysis; conduct a reference analysis; alert of logic errors; calculate pole loading from the inputted data; and display the results generated from the pole loading calculations. The computer readable codes embodied in the article of manufacture also cause the computer to store data input into the computer, the data may include data pertaining to the pole, power conductors, communications cables, fiber optic cables, transformers, equipment, guy wires, ice, wind, and pole loading standards. The article of manufacture also causes the computer to generate least one display screen having a graphical user interface so that the user may input pole loading data. Other data input screen displays the article of manufacture may cause the computer to generate include displays for: general data input; pole data input; conductor data input; transformer data input; equipment data input; transformer data input; and guy wire data input.

The article of manufacture may also be embodied to cause the computer to graphically display on a computer screen any of the following: pole height versus horizontal shear load; pole height versus bending moment; pole height versus compressive stress; pole height versus deflection; a pie chart showing component moments as a percentage of the total moment; a bar graph showing component moments as a percentage of pole capacity at groundline.

The article of manufacture may be embodied in any of the following forms: CD-ROM; floppy disk; optical disk; and other forms well known to those of ordinary skill in the art.

System

The present invention may also be embodied in a system for determining pole loading having: a computer processor; a memory for storing input pole data and for storing input pole loading data; computer executable instructions for being executed on the computer processor, the computer executable instructions for calculating the loading on the pole from the input pole data and the input pole loading data stored in the memory; and a means for outputting the results generated by the computer executable instructions when executed on the computer processor. The means for outputting the results may be computer screen displays. The results may be in the form of printed summary reports, graphical screen displays, charts, and graphs.

The system memory is embodied to store at least one of the following: general data inputs; pole data inputs; conductor data inputs; transformer data inputs; equipment data inputs; guy wire data inputs; and wind and ice data inputs. The system further has at least one of the following computerized features: tally of pole loading; a real time screen display indicating the percentage of a pole's bending moment capacity used due to the loading; warning logic; related analysis; and reference analysis. The system's computer executable instructions generate a plurality of screen displays and generate a plurality of data input pages, a data input page is generated at least one of the following: general data input; pole data input; conductor data input; transformer data input; equipment data input; transformer data input; and guy wire data input (as seen in FIGS. 48, 65, 66, 72, 74, and 76). The system outputs the results of the pole analysis to are graphical screen displays showing at least one of the following: summary report; pole height versus horizontal shear load; pole height versus bending moment; pole height versus compressive stress; pole height versus deflection; a pie chart showing component moments as a percentage of the total moment; and a bar graph showing component moments as a percentage of pole capacity at groundline (FIGS. 82a-82f and 83a-83f).

A computerized memory is also provided for, the computerized memory for storing data for access by an application program being executed on the computer. The memory operatively associates with a data structure for purposes of storing and organizing data pertaining to pole loading. The data also includes data pertaining to pole loading code standards, transverse pole loading data, vertical pole loading data. The memory also stores pole characteristic data, general data inputs, pole data inputs, conductor data inputs, transformer data inputs, equipment data inputs, transformer data inputs, guy wire data inputs, equipment data inputs, wind data inputs, and ice data inputs.

The memory further stores and organizes data for at least one of the following: pole height versus horizontal shear load; pole height versus bending moment; pole height versus compressive stress; pole height versus deflection; a pie chart showing component moments as a percentage of the total moment; and a bar graph showing component moments as a percentage of pole capacity at groundline.

The memory may be accessed by the user, and be edited by the user, such that data may be added, modified, or deleted therefrom. The memory also stores the pole code loading standards as defaults, so that a user does not have to repeatedly enter the code loading standards for each new pole analysis. Rather, the user need only select which of the code standards is needed for the analysis. This saves time, and avoids the errors that would be associated if the user had to manually input all of the particulars of the code loading standards for each pole analysis.

Architecture and Description of the Screen Displays Generated by the Computer Software Program when Executed on a Computer Processor

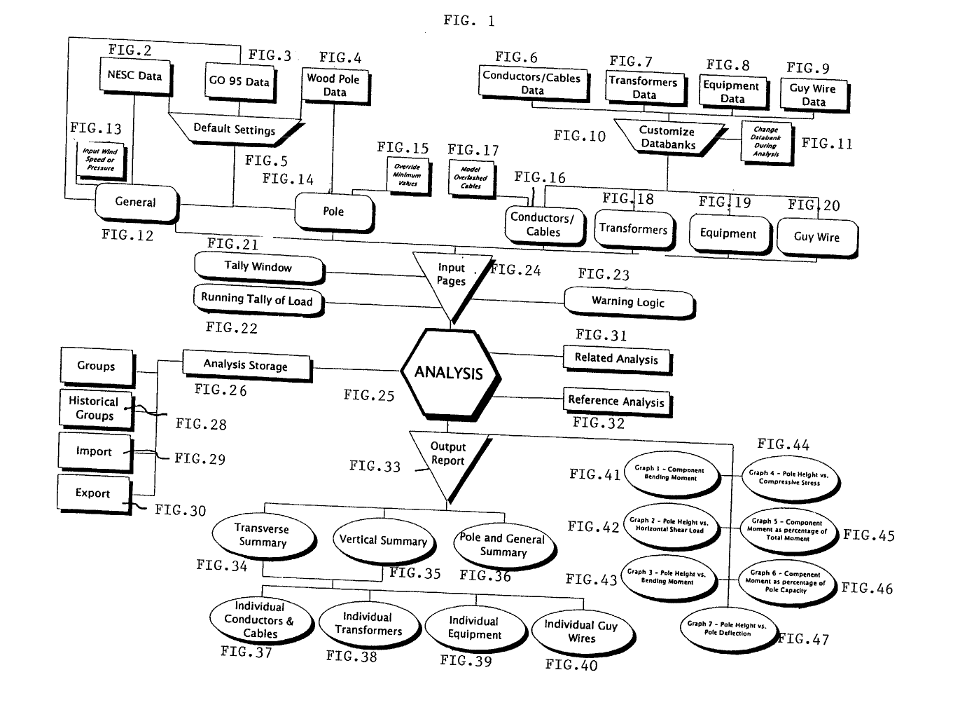

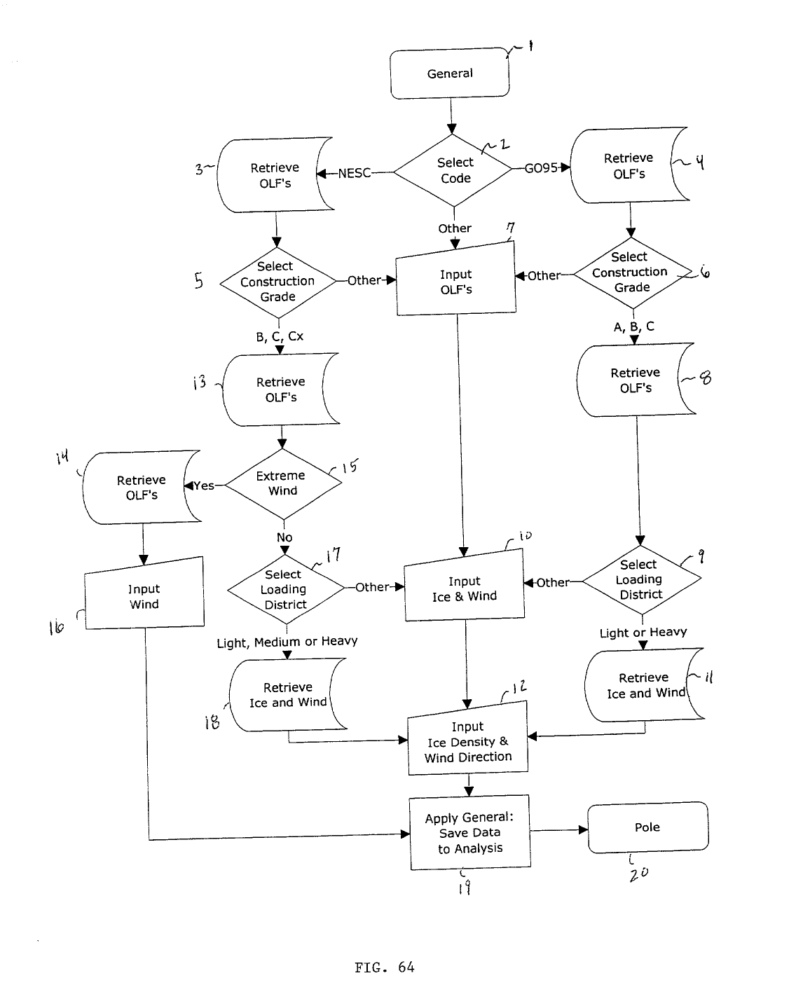

It is noted that the description of the pole loading software system, methodology and computer program described below product begins with a general description of the overall architecture of the software program (FIG. 1), followed thereafter with a detailed description of the functionality of the software (FIGS. 2-63, 65-80, and 82-102), and thereafter with a description of the operation of the computer software (FIGS. 64, 81, 103-106). The computer software program may be embodied to have preloaded data, for example, pole loading safety standards. The computer program causes the computer to store and organize input data in databanks, causes the computer to perform mathematical calculations from the input data, and causes the computer to generate and output the results of the calculations. The software program also causes the computer to generate screen displays that graphically show the outputs of the computer software program after being executed on the computer. These outputs may be embodied in the form of summary reports, printed media, screen displays, charts and graphs. It is further noted that applicant's mark “O-Calc” TM appears on a plurality of the screen displays shown in the figures shown herein.

Turning now to FIG. 1, shown therein is a representation of the overall architecture for the system, method, and computer program product of the present invention. For overview purposes, the architecture indicated by FIGS. 1-47 is first described. Then a more detailed description follows describing the functional aspects and operational aspects of the software program in greater detail in FIGS. 48-63, 56-80, 82-102. Next, a detailed description of the flow charts reflecting the operation of the software program is described (FIGS. 64, 81, 103-106).

Turning now to FIGS. 2, 3, and 4, these figures show default settings available to the user to select when beginning an analysis. In general, a pole analysis means that a study of the loading on a pole is being undertaken, so that the loading may be calculated and output to the user. The user may begin an analysis by selecting either the National Electrical Safety Code (NESC) pole standards (FIG. 2), the California General Order 95 pole standards, or national pole standards. These are the default settings, indicated by FIG. 5. The computer executable software program has the default data pre-loaded and pre-stored therein. As discussed below, the user may change these defaults.

FIG. 6 shows the databank for conductors and cables, FIG. 7 shows the databank for transformer data, FIG. 8 shows the databank for the equipment data, FIG. 9 shows the databank for guy wire data. These databanks are loaded with pre-stored data. FIG. 10 shows the databanks may be customized on demand by the user, and FIG. 11 shows that a user may change a databank during a pole analysis, in the manner described below.

FIG. 12 indicates the general data input page, wherein the user inputs into the computer the pole loading code standards selected, and FIG. 13 indicates the data input page for wind speed or pressure (described in detail below). FIG. 14 indicates the input page for pole data, and FIG. 15 indicates the data input page that allows the user override the default settings in the general pole data page shown in FIG. 14.

FIG. 16 indicates the data input page for cable and conductor loads, and FIG. 17 indicates the data input page for overlashed type cables, described in detail below. FIGS. 18-20 indicate the data input pages for transformers, equipment, and guy wires loads respectively. FIG. 21 indicates the tally of all the loads placed on the pole from a conductor or a cable. The running tally in FIG. 22 indicates the percentage of total pole load capacity used by all the pole loading, from whatever source, updated in real time.

FIG. 23 shows a warning logic feature, that serves to alert the user that the input data is suspect. For example, if the user inputs data the pole is entirely underground, or that a transformer is placed at a location 15 feet above the top of the pole tip. The software program alerts the user of this logic error. The user then has an opportunity to rectify the error before continuing with the pole analysis. FIG. 24 indicates that data gathered from the data inputs in FIGS. 12-23 is input into the computer processor and analyzed.

The analysis indicated by FIG. 25 is the computerized processing of all of the input data to thus calculate the loading on the pole. This analysis further generates output reports. FIG. 26 indicates that the analysis of the pole loading is stored in databanks, such as the groups and historical groups indicated in FIGS. 27 and 28 respectively, described in detail below. The analysis may also be imported and exported among users by email, disk, carrier wave transmissions, or other manners well known to those of ordinary skill in the art, as indicated by FIGS. 29 and 30.

Additionally, FIGS. 31 and 32 provide for related analyses and reference analyses respectively. A reference analysis allows for the analyses of poles with similar construction, so that the user does not have to repeatedly reenter pole data. The reference pole data is saved in a databank, and may then by used as a template for other pole analyses. The related analysis tool, indicated in FIG. 31, however, is a “what if” tool. Essentially the related analysis tool allows the user to open the database for an existing pole, clone the data for a pole, and then use the cloned pole and manipulate the loading on that pole, by adding cables, transformer, equipment, and other loading variables to the pole. The user may then study the output, as analyze the “what if” scenario ramifications. For example, the user may want to know if adding another transformer to a pole would cause the pole to become overloaded. The user may use this feature in which the software program calculates and outputs the results of the “what if” scenario. The user may then quickly assess if the transformer can be safely added to the pole. The original data for the pole that is cloned remains unaltered in a “what if” scenario.

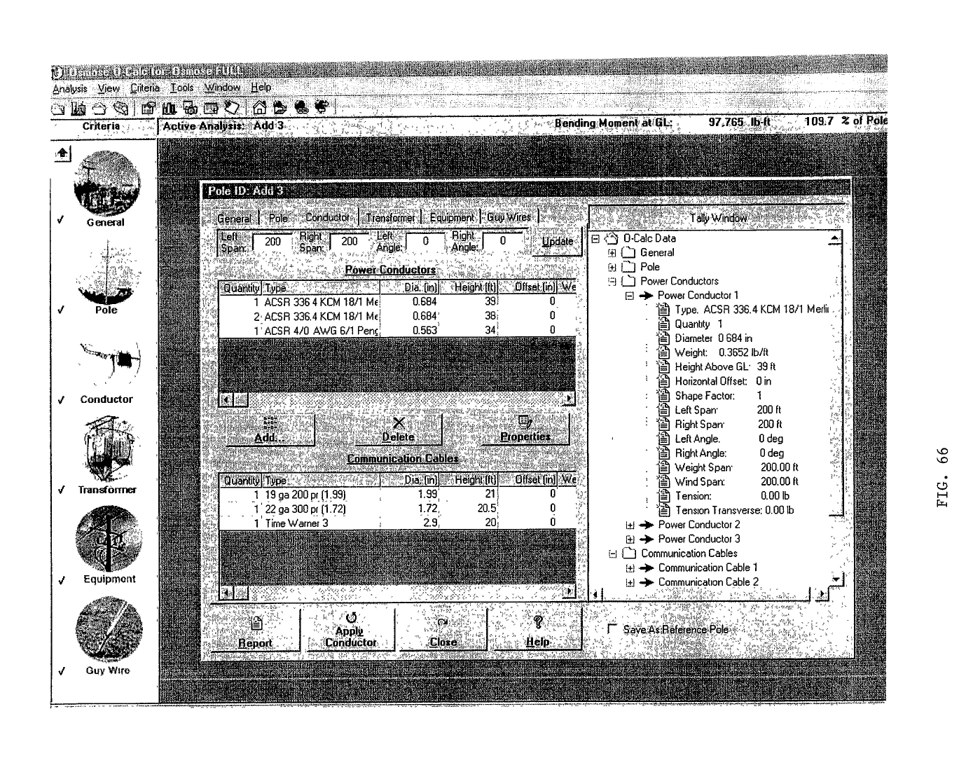

Next, the computer processor, after analyzing all the input data, generates an easy to use easy to read output report. An example of an output reports appears in FIGS. 82 and 83. It is noted at this point that any numerical values that appear in any of the data input fields, or data input boxes herein, are for illustrative purposes only, and are not intended to limit the scope of this invention. Thus, for example, the input numbers in FIG. 66 are for illustrative purposes. The output report may be embodied as a color coded document, wherein the numerical values in blue indicate input data, and the numerical values in black indicate data output by the computer program. FIG. 36 indicates the pole and general summary. FIG. 34 and 35 indicate the output transverse and vertical summaries of the pole loading, respectively. FIGS. 37-40, indicate the cable and conductor, individual transformer, individual equipment, and individual guy wire loading summaries. Examples of these summaries are also shown in FIGS. 82-83.

FIGS. 41-47 indicate the graphical displays that may be generated and output by the computer software program, taking into account all of the input data. FIG. 41 indicates component bending moment, FIG. 42 indicates pole height versus horizontal shear load, FIG. 43 indicates pole height versus bending moment, FIG. 44 indicates pole height verus compressive stress, FIG. 45 indicates component moment as a percentage of total moment, FIG. 46 indicates component moment as a percentage of pole capacity, and FIG. 47 indicates pole height versus pole deflection.

With the general features of the system, methodology, and computer program product of the pole loading software set forth above, the specifics of each aspect are described in greater detail. The pole loading software, i.e. computer program, may be embodied in the form of a CD-ROM, optical disk, hard drive, magnetic tape, floppy disk, carrier wave signal, and other forms well known to those of ordinary skill in the art.

The user initially executes the software program on a computer processor. The executed software program causes the computer to generate a plurality of screen displays, with a plurality of data input boxes (that may be embodied as data input fields or data dialog boxes). FIG. 48 shows the computer generated screen display for the “General” data input screen, caused to be generated by the computer when the computer processor executes the computer software program. For ease of understanding, it is noted that words appearing in quotation marks throughout this written description are the actual words appearing on the screen displays caused to be generated when the software program is executed on the computer.

In FIG. 48, the tab for the word “General” appears raised, and this informs the user that the “General” data input page is activated and ready to receive data inputs. The user interacts with the screen displays described herein by manually inputting data into the data input boxes, by clicking on these features with a mouse to move the cursor to a particular data input box. For example, clicking on the “Analysis” feature in FIG. 48 opens a pull down menu for that feature, and the user may click on a data input box to move the cursor there, or the user may use the tab key on the keyboard to move the cursor to different data input boxes.

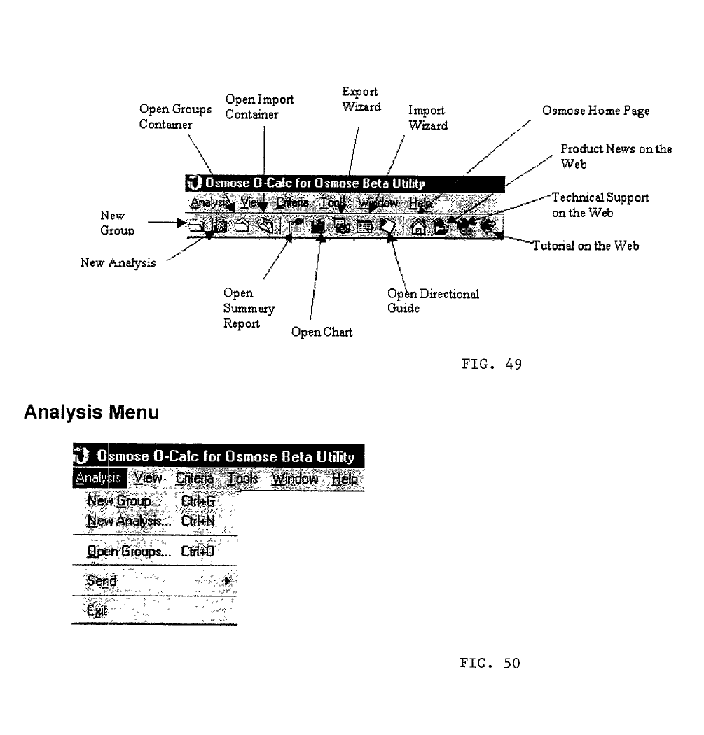

The tool bar on the top portion of the screen display page in FIG. 48 is a graphical user interface and comprises the following pull down menus: “Analysis;” “View;” “Criteria;” “Tools;” “Window;” and “Help.” The toolbar appears in FIG. 49, and it allows the user access the many features of the pole loading software program.

FIG. 50 shows the pull down “Analysis Menu,”wherein the user may select a “New Group” from the pull down menu to create a new group to store pole analyses. “New Analysis” allows the user to start a new analysis on a pole. “Open Groups” allows the user to open a stored analysis, and “Send” allows the user to email an “Analysis” to another user.

In FIG. 51, the next pull down menu is shown, this being the “View Menu.” It has an “Import Container” feature that opens all the “Analyses” that were exported from one user to another, a “Chart/Graphs” feature that displays a graph for the “Analysis” that is open, a “Summary Report” feature that displays the “Summary Report”, a “Reference Poles” feature that serves as a template for repetitive construction of poles of similar construction, a “Directional Guide” feature that shows the orientation for line angles and guy wires, and “Tool Bar” and “Status Bar” features that toggle these functions on and off.

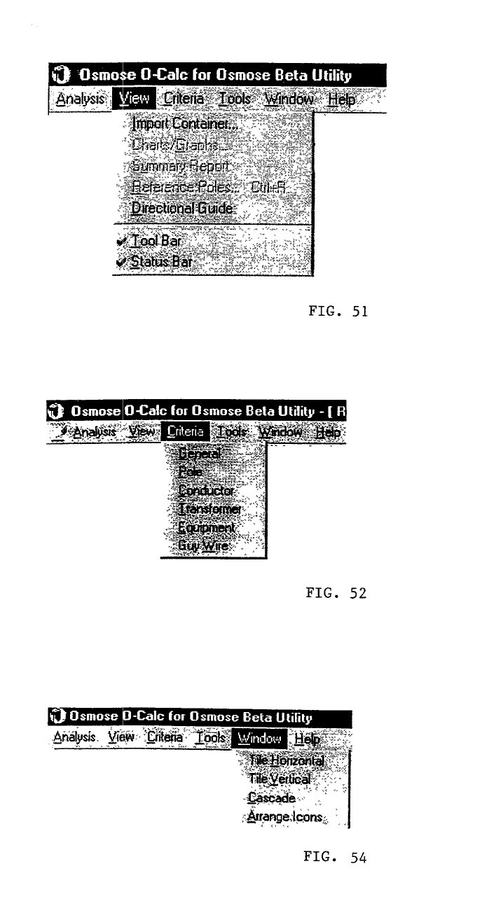

In FIG. 52, the next pull down menu is the “Criteria Menu.” This feature allow the user to edit any of the following criteria in an open “Analysis”: “General” data, “Pole” data, “Conductor” data, “Transformer” data, “Equipment” data, and “Guy Wire” data.

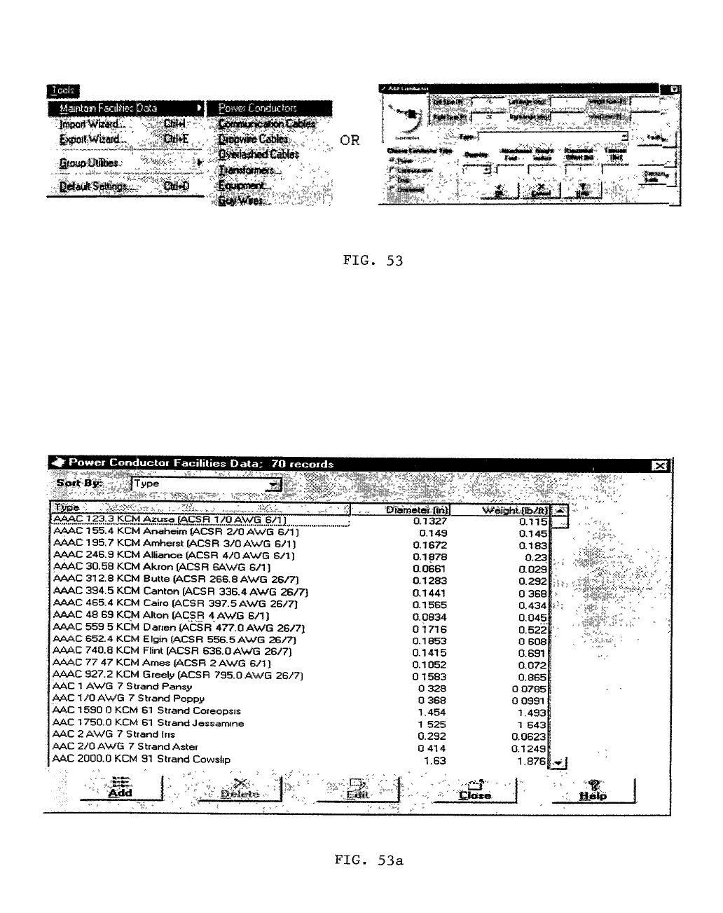

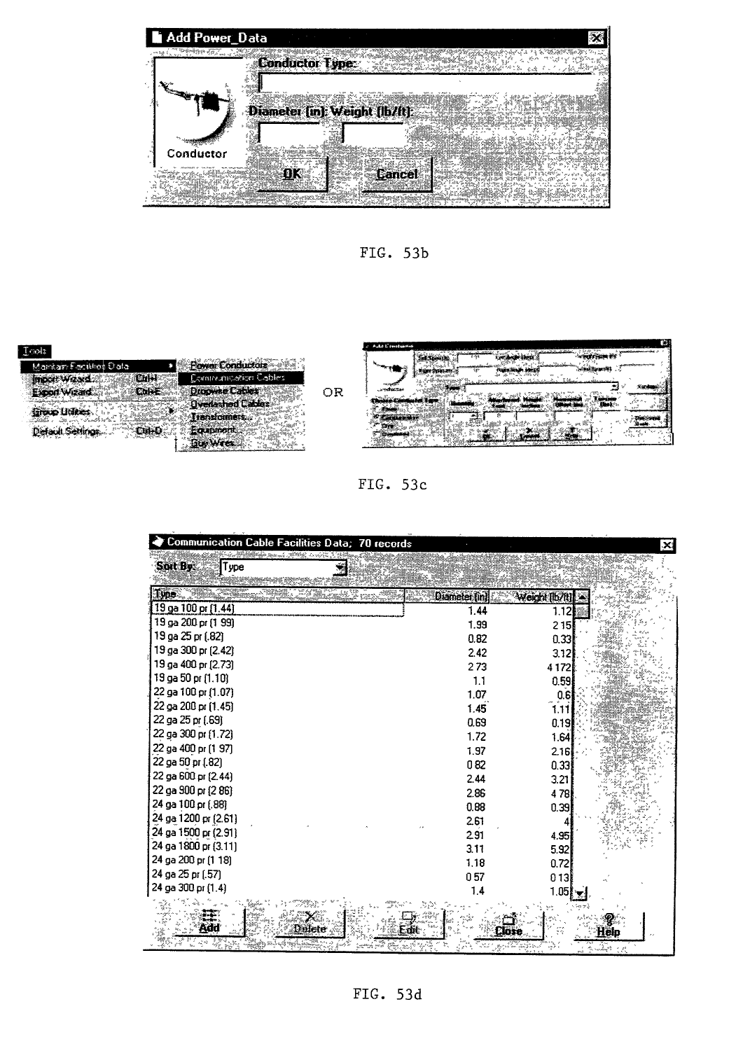

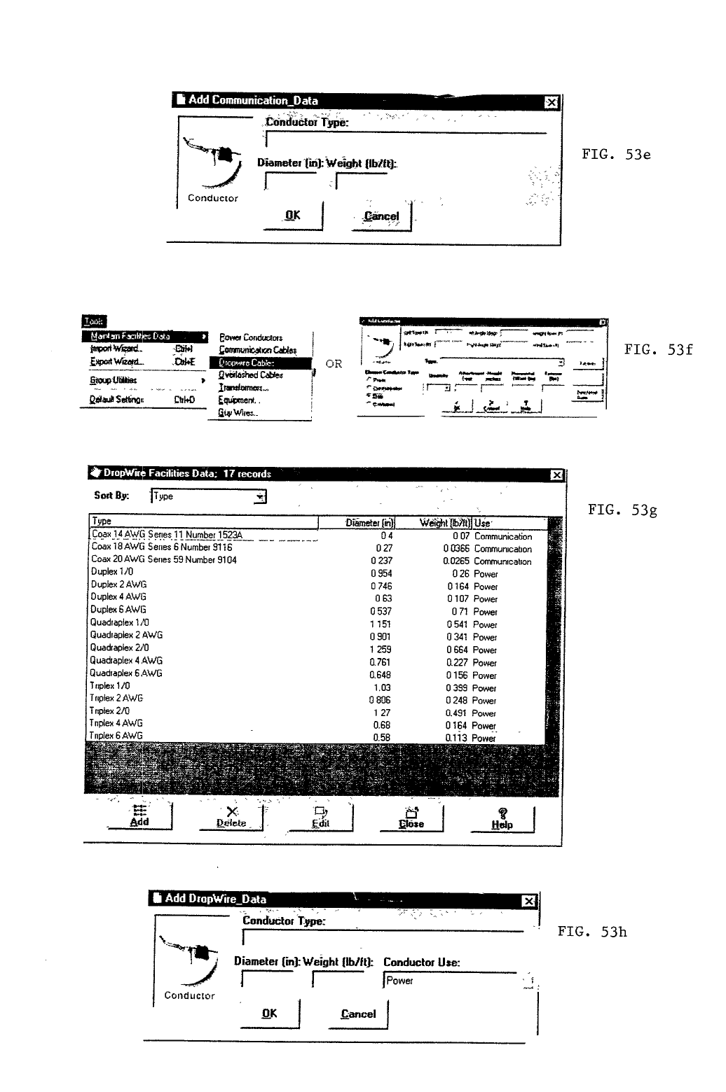

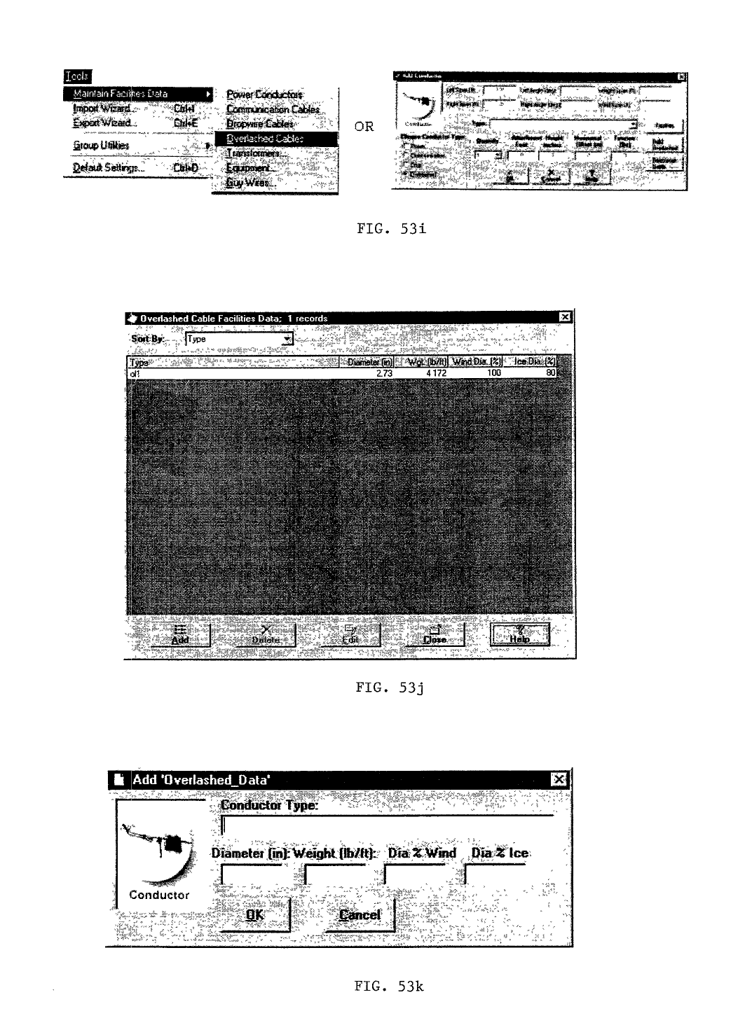

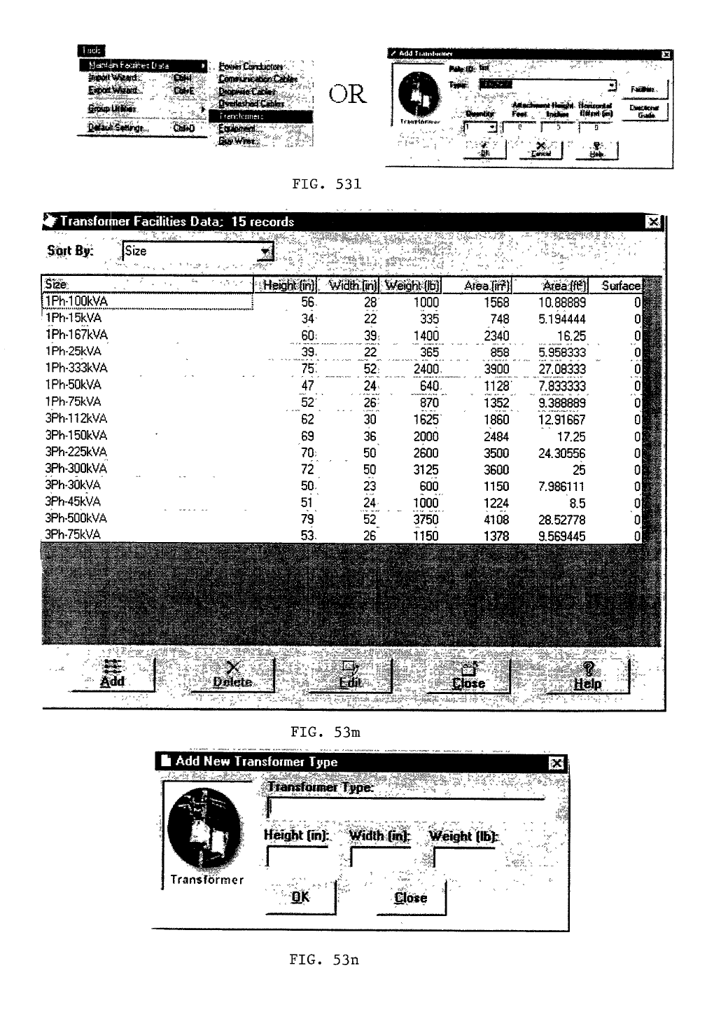

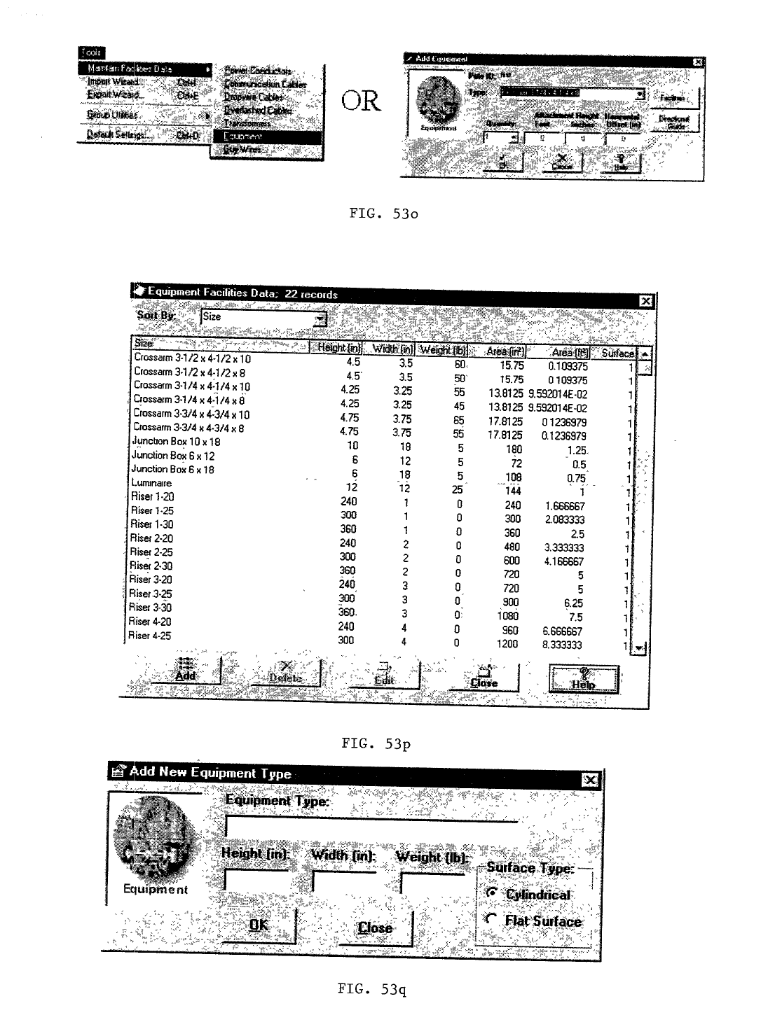

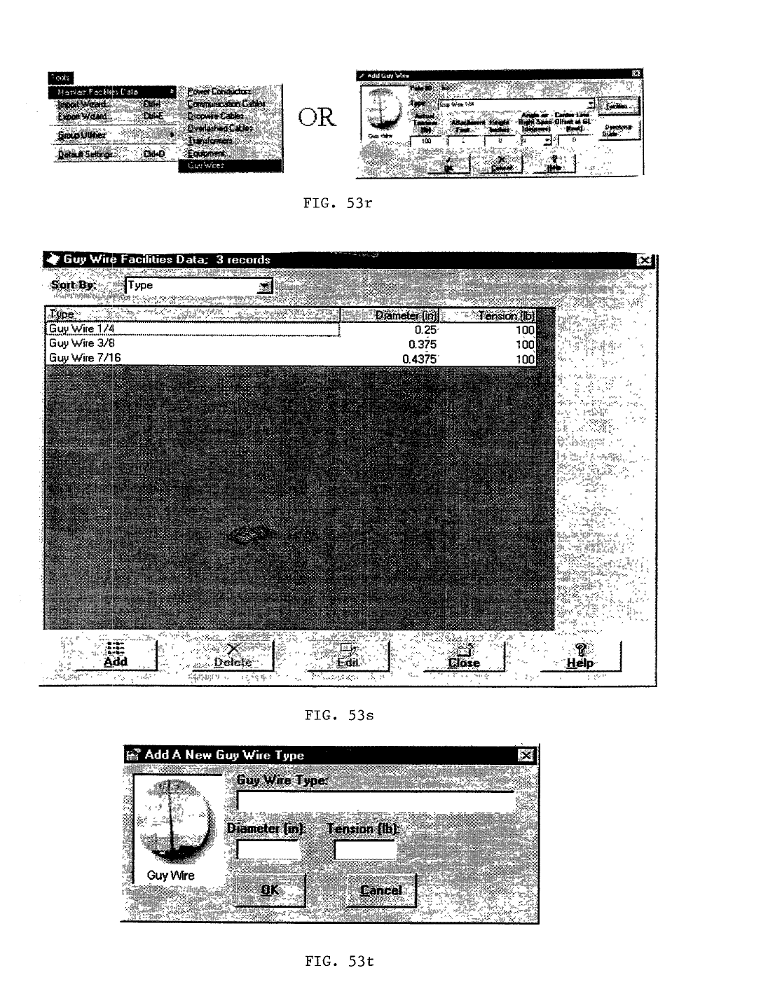

The next pull down menu in FIG. 53 is the “Tool” menu, that allows the user to “Maintain Facilities Data.” The software may be embodied to have preloaded databanks containing information on the specifications for “Power Conductors,” “Communications Cables,” Dropwire Cables,” “Overlashed Cables,” “Transformers,” Equipment,” and “Guy Wires.” The user may use these databanks when conducting an analysis, or may bypass these databanks and input data specific to the user's needs and add to the databanks content. To do this, the user selects the “Maintain Facilities Data” option under “Tools”, and clicks on and thus highlights any of the items listed therein. For example, the user may highlight “Power Conductors” (FIG. 53) and the “Power Conductor Facilities Data” window appears, which may hold previously entered power conductor data. If the user is unable to find the desired data from the databank, the user may click on the “Add” feature in FIG. 53a to add data to that databank for a new “Power Conductor.” The user would then fill in the data input fields in FIG. 53b, by inputting the “Type,” “Diameter,” and “Weight” of the “Power Conductor.” In this manner a new “Power Conductor” is added to the “Power Conductor Facilities Databank” shown in FIG. 53a.

Following the same procedure, the “Maintain Facilities Data” feature shown in FIG. 53 may be used to add, modify, or delete records from the “Power Conductor” databank, the “Communication Cables” databank, the “Dropline Cables” databank, the “Overlashed Cables” databank, the “Transformer” databank, the “Equipment” databank, and the “Guy Wire” databank. This is all shown in FIGS. 53c-53t.

In FIG. 54, the pull down menu for the “Window” feature allows the user to display more than one open “Analysis” or “Chart” in “Tile Horizontal,” “Tile Vertical,” “Cascade,” or “Arrange Icons” fashion. In FIG. 55 the next pull down menu is the “Help” menu. This feature allows access to the table of “Contents” for the software program, and several other features as shown in that figure.

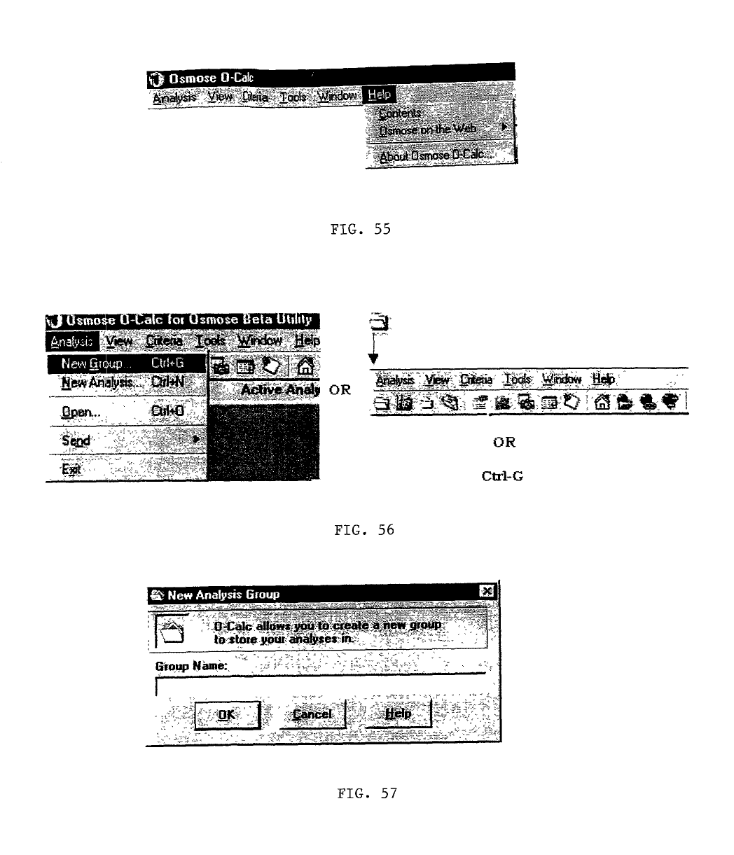

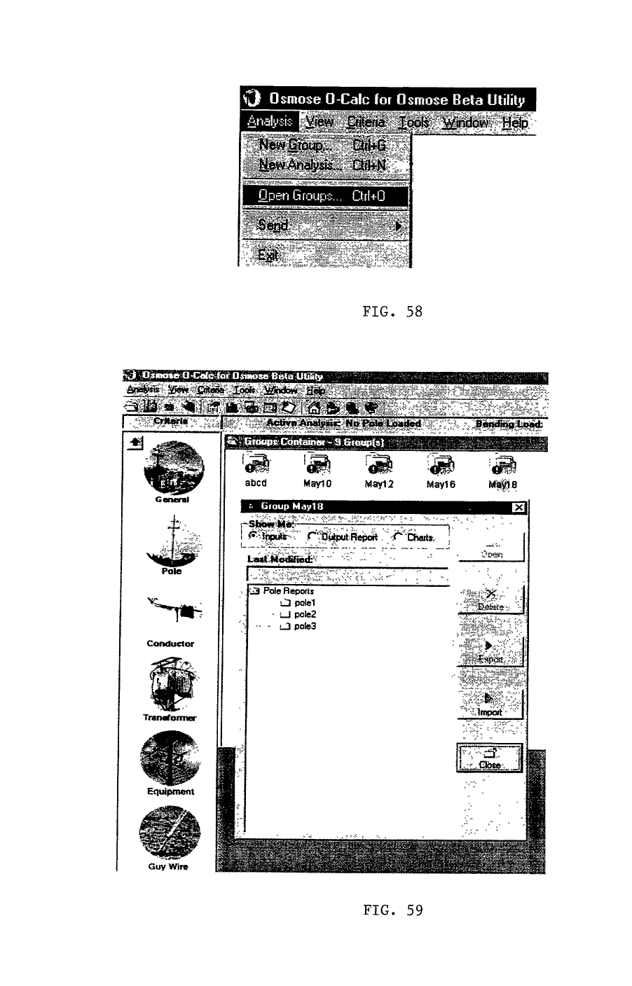

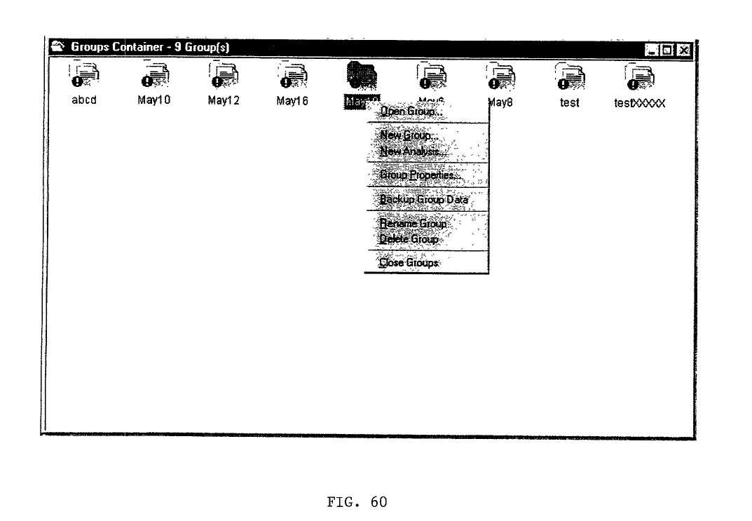

In FIGS. 56 and 57, the “New Groups” analyses are selected from the “Analysis” pull down menu. This feature allows analyses to be grouped, named, and then stored, via the interactive screen display shown in FIG. 57. To open a stored group, the “Analysis” menu is selected, as shown in FIG. 58, and the “Open Groups” option is selected. Once the “Open Groups” option is selected, the “Group Container” appears, seen in FIG. 59, that displays all the previously saved groups. The icon for any of the groups may be double clicked, and a window appears with the group name in the caption bar, and a listing of pole analyses in that group, as shown in FIG. 59. As further shown in FIG. 59, the any of the inputs, output reports, or charts may be selected, and the user may highlight a pole analysis and click it open, by clicking on the “Open” icon. Additionally, when a group's icon is selected, a drop down menu appears providing several options, as shown in FIG. 60. The user may click on any of these options to find out more information about the “Groups,” as shown in FIG. 60.

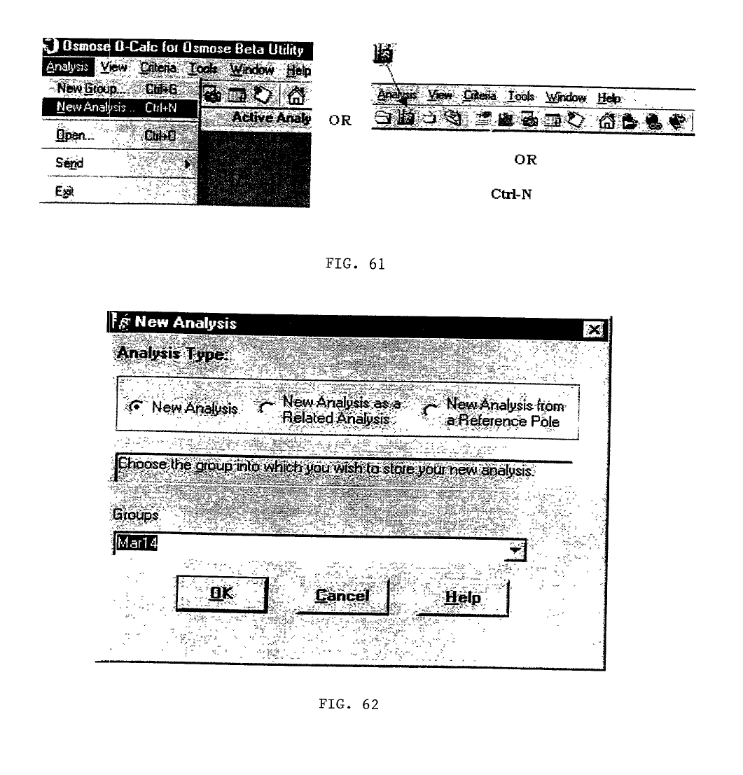

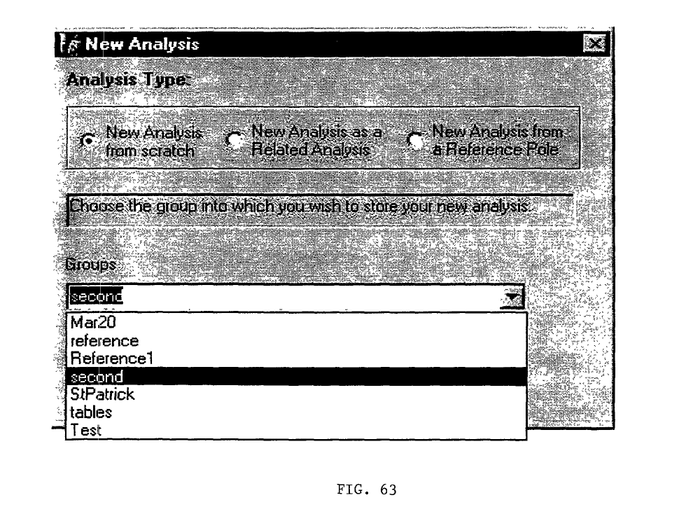

The following describes the process a user follows to conduct an new analysis on a pole. In order to create a new pole analysis the user first goes to and selects the “Analysis” feature, as shown in FIG. 61. The user then selects “New Analysis,” and the screen display in FIG. 62 appears, and the user selects “New Analysis” as further shown in FIG. 62. It is noted that the user may in the alternative select “New Analysis as a Related Analysis,” or “New Analysis from a Reference Pole,” these features described in greater detail below. Next the user inputs the group name this pole analysis is to be stored under, by filling in a name in the input box in FIG. 62. If, however, there is a preexisting group the user needs to store the analysis in, the user need only select the “Group” and then click on the “OK” icon, the “OK” icon is obscured in FIG. 63, but is visible in FIG. 62.

FIG. 48 shows a graphical user interface data input page generated when the software is executed. It is noted several of the features appearing on this screen display (“Analysis,” “View,” “Criteria,” “Tools,” “Window,” and “Help”) have been described above. This is the “General” data input page for a “New Analysis” of a pole. It is noted that the “General” tab appears raised with respect to the tabs for “Pole,” “Conductor,” “Transformer,” “Equipment,” and “Guy Wire.” When the user selects any of these features, they appear as a raised tab, the way “General” appears in FIG. 48. The software allows data to be input into the “General” data page by using a mouse to click on the data field and entering the data, or by using the keyboard “tab” feature to select the desired data field and then entering data therein.

The following is a list of definitions for the terminology appearing in the “General” data input page shown in FIG. 48:

OLF: This is the Overload Capacity Factor and is used throughout this description. This is a load multiplier as required by the safety codes.

Code: The safety code used for load calculations. Can be NESC Standard, NESC Alternate, General Order No. 95 (California) or Other.

Construction Grade: NESC can be Grade B, C or C at crossing. GO 95 (General Order No. 95) can be Grade A, B, or C. Clicking the “Other” button allows you to set your own overload factors.

Loading District: The loading district used for ice and wind loading condition.

NESC can be Light, Medium, or Heavy.

GO 95 can be Light or Heavy.

Clicking the “Other” button allows you to set the loading conditions to any value.

Transverse Wind OLF: The Overload Capacity Factor applied to the transverse wind loads.

Transverse Wire Tension OLF: The Overload Capacity Factor applied to transverse wire tension loads.

Vertical Load OLF: The Overload Capacity Factor applied to vertical loads.

Ice Radial Thickness (in): The amount of radial ice added to conductors.

Wind Load Applied (lb./ft²): Wind pressure expressed in pounds of force applied to each square foot of conductor surface area including ice if required.

Wind Speed Applied (mph): Wind speed in miles per hour corresponding to the specified wind pressure.

Apply Extreme Wind: Indicates whether Extreme Wind criteria were used for this analysis.

Apply Reverse Wind: Indicates whether the wind is reversed for Transverse Load Evaluations.

Ice Density (lb./ft³): The density of ice in pounds per cubic foot.

The “General” data input page shown in FIG. 48 allows the user to select the requisite pole loading code. As shown, the user may select either National Electric Safety Code (NESC) pole standards, California General Order 95 pole standards, or National Electric Safety Code Alternative standards. If any of these are selected, the computerized system automatically uses default values to conduct the pole analysis. Such a selection automatically disables all of the remaining dialog boxes displayed in the screen display in FIG. 48, so that a field worker, for example, does not err by altering the standards. However, if the “Other” option is selected, the data entry fields may be filled with any data the user desires. For example, the user may enter the “Loading District,” the “Construction “Grade,” and conduct an “Extreme Wind” analysis. Another feature of the software is the “Extreme Wind” feature, that allows the input of either the “Extreme Wind Speed” (mph) or “Extreme Wind Pressure” (lb./ft. square), when the value of one is input into the data input field, the value of the other is automatically calculated and displayed by the software program.

There are several other features shown in the screen display of FIG. 48 of particular interest. Each of these will now be described in detail. The icons vertically arranged to the left in the screen display are for: “General” ( general pole data); “Pole;” “Conductor;” “Transformer;” “Equipment;” and “Guy Wire.” The user may, at any time, click on any one of these icons and access the data page input page for each. For example if the “General” icon is selected, the “General” data input page would appear in the screen display. If the user then wants to go to the transformer data input page, the user would click on the “Transformer” icon. This feature thus allows the user rapid access to other data input pages. Next, to the right of the screen display is a “Tally Window” box, having a plurality of pull down menus. The user may select any one of the “General,” “Pole,” “Power Conductors,” “Communications Cables,” “Transformers,” “Equipment,” or “Guy Wires” folders, and open the folder to display previously entered data. The folder is expanded and compressed by clicking on the +/− checkmark next to each of the folders. Another feature shown in FIG. 48 is the “Save as a Reference” pole feature, that allows the pole data to be saved as a reference pole, that is, the pole data may be saved and then used as a template for similar poles with similar specifications. This feature is described in greater detail below.

Several additional features caused to be generated by the software program being executed on the computer are shown in the screen display of FIG. 48. Located above the data entry window are “Active Analysis” and “Pole Capacity” indicators. These provide the pole identification number and percentage of pole capacity being utilized due to the loading on the pole, respectfully. On the bottom of the screen display in FIG. 48 are buttons for “Report,” “Apply General,” “Close,” and “Help.” The “Report” button causes the software to provide an “Output Report” that the software program causes the computer to create from the input data pertaining to the pole loading and pole specifics. The “Apply General” button saves the input data for that page, and also causes a checkmark to appear next to that object in the “Criteria Bar,” as shown in FIG. 48. The checkmark indicates that the user has input data for that data page.

FIG. 65 shows the “Pole” data input page, accessible by clicking on the raised tab for the same. In this graphical user interface screen display caused to be generated when the software is executed on the computer, the user inputs data pertaining to the pole under analysis. A definition list for the terminology used in the pole data input page is as follows:

Pole ID: The pole number or identifier, which can include up to 50 characters. The analysis is considered to be the “Parent” unless it is a “Related Analysis” to another “Parent” analysis.

Related Pole: If the Pole ID refers to a new pole analysis that is not related to any other, it will state Parent in this entry. If the Pole ID refers to a pole that is related to a “parent” analysis, the Pole ID of the parent pole is shown here.

Label 1: A second identifier for the pole such as Region, District, Line etc.

Label 2: A third identifier for the pole such as Region, District, Line etc.

Label 3: A fourth identifier for the pole such as Region, District, Line etc. Length/Class: Length and Class of the pole.

Pole Species: Species of the wood pole.

Fiber Stress (psi): The strength of the wood based on the ANSI 05.1 (American National Standard Institute) fiber stress values for the species of pole.

Elastic Modulus (psi): The modulus of elasticity of the pole material in pounds per square inch. The default values in the program are the mid-range values for each species. These values can be changed on the default page or on the Pole Data Input Page for a specific analysis.

Min. Circ. at Tip (in): ANSI 05.1 minimum circumference in inches for the pole tip.

Actual Circ. at Tip (in): Actual tip circumference in inches, which overrides the minimum dimension.

Min. Circ. at 6 feet (in): ANSI 05.1 minimum circumference in inches, 6 feet from the butt of the pole.

Min. Circ. at GL (in): Starting with the minimum circumference in inches at 6 feet from the butt, the linear taper of the pole to the tip is used to compute the circumference of the pole at the groundline based on the setting depth.

Actual Circ. At GL (in): An actual groundline measurement can be input and it will override the minimum dimension.

Code Setting Depth (ft): The setting depth in feet as specified by the appropriate code, ANSI 05.1 or GO 95.

Actual Setting Depth (ft): The actual setting depth in feet for the specific pole used in this analysis.

The following terminology is used in the Summary Report shown in FIGS. 82 and 83.

Pole Height Above Ground (ft): The total length of the pole minus the Actual Setting Depth.

Pole Circumference Taper (in/ft): The linear taper of the pole is based on the actual circumference at 6 feet from the butt and the minimum circumference at the tip, unless the groundline or tip dimensions were overridden with actual dimensions.

Pole Density (lb./ft³): The weight density of the pole material expressed in pounds per cubic foot.

Pole Weight Above GL (lb.): The weight of the pole section above ground in pounds.

Pole C.G. Above GL (ft): The center of gravity for the pole section above ground in feet.

Projected Area Above GL (ft²) The pole surface area in square feet that is exposed to the specified wind pressure.

Pole Moment Capacity (lb.-ft): the bending moment capacity of the pole in pound feet based on the groundline circumference and the designated fiber stress.

The user inputs the above data in the appropriate following data input boxes: “Pole ID” (identification); “Related Pole ID” (fills in automatically when performing a related pole analysis); “Label 1”, “Label 2”, and “Label 3” (optional fields to further identify a pole); “Pole Species”, “Length”, and “Class”, each selected from a drop down menu display; “Default” and “Actual” groundline (GL) circumference, and “Default” and “Actual” tip circumference. These values may be overridden by selecting the override feature. The “Default” pole depth setting for the selected code and pole length are automatically used by the software program, or the “Actual Setting Depth” may be used, so that these values override the defaults. The “Modulus of Rupture,” “Modulus of Elasticity,” and “Density” appear as default values for the particular tree species. However, these values may be overridden by changing the pole data values.

The “Column Buckling Height above GL” value determines the height of the column to be used in the buckling analysis. The default value is for the full height of the pole above the ground, this being conservative. An alternate value may be entered. If buckling is not a limiting criterion when analyzing the full pole height for the column, then buckling would not be a limiting criterion if analyzed with a shorter column height. On the other hand, if buckling is a limiting criterion using the full pole height above ground, recomputing the buckling analysis with a shorter column height, for example the height of the lowest guy wire attachment, may show that the pole is not limited due to buckling.

The “Buckling Constant” of Euler's formula defines the end conditions of the column, i.e., fixed, hinged, round, etc. The default of 2 is often used with an unguyed structure. Euler's theorem predicts when a column will collapse due to loading. In such an analysis, the critical load at which a column will buckle is equal to (n squared) multiplied by (the modulus of elasticity (E)) multiplied by (the moment of inertia (I)) divided by (a default constant multiplied by the length of the column) squared. Euler's formula and its applications for different end conditions of a pole are well known to those of ordinary skill in the art.

However, a safety factor is applied when using the formula. For example, wood poles vary from pole to pole, etc. A safety factor of 3 may be used for dead end and large angles, and a safety factor of 1.33 may be used for heavy ice. Other safety factors are well known to those of ordinary skill in the art. “Section Height %” is the percentage of the column height up from the bottom where the circumference at that point is used as a constant circumference for the entire column. The default is set to 33.33%, which is ⅓ the distance from the GL to the “Column Buckling Height.”

FIG. 66 shows “Conductor and/or Cable” data input page generated by the computer software program being executed on the computer, as indicated by the raised conductor tab in that figure.

The following is a list of definitions for the terminology utilized in FIGS. 66-71 for conductors:

Qty: The number of power conductors attached at this height.

Horiz. Offset (in): If the conductor is not located at the pole or balanced by an equivalent conductor on the other side of the pole, this horizontal offset distance will account for the moment created by the weight of the conductor measured from the pole surface to the conductor perpendicular to the lead of line in inches.

Cable Dia (in): The outer diameter of the conductor in inches.

Cable Weight (lb./ft): The weight of the conductor in pounds per foot.

Cable Tensions (lbs.): This input is only required for angle structures. The value should approximate the design tension and the program will apply the Wire Tension Overload factor in pounds.

Left Span (ft): The length of the conductor span in feet from the pole being analyzed to the pole on the left. For roadside poles, the left span is located as the observer looks toward the pole with the street beyond the pole.

Right Span (ft): The length of the conductor span in feet from the pole being analyzed to the pole on the right. For roadside poles, the right span is located as the observer looks toward the pole with the street beyond the pole.

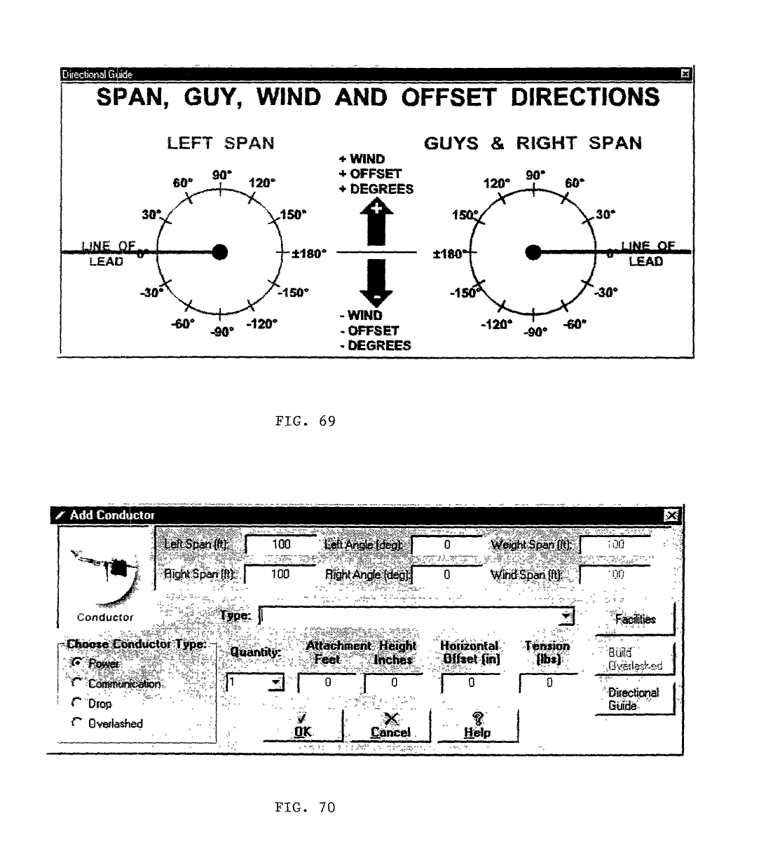

Left Angle (deg): The angle of the left span in degrees. A tangent structure will have zero for both the left and right angle. Consult the Directional Guide for orientation of the angles and wind direction (FIG. 69).

Right Angle (deg): The angle of the right span in degrees. A tangent structure will have zero for both the left and right angle. Consult the Directional Guide for orientation of the angles and wind direction (FIG. 69).

Cable Weight (lbs.): Total conductor weight in pounds without the overload factor.

Ice Weight (lbs.): Weight of the ice in pounds on the conductor without the overload factor.

Total Weight (lbs.): Total weight of the conductor and ice in pounds if applicable without the overload factor.

The following terminology is used in the Summary Report in FIGS. 82 and 83:

Wind Span (ft): The effective span in feet exposed to the wind accounted for by one-half of each span. If it is an angle structure, the program adjusts the length of the resulting span to that, which is perpendicular to the transverse wind.

Weight Span (ft): The total span in feet for determining the conductor weight figured using one-half of each span regardless of the angle of the line.

Offset Moment (lb.-ft): Moment created by the distance that the weight of the conductor is offset from the center of the pole in foot-pounds without the overload factor.

Wind Load (lbs.): Wind load in pounds on the quantity of conductors in this entry without the overload factor.

Wind Moment (lb.-ft): Moment created by the wind load in foot-pounds on the quantity of conductors in this entry without the overload factor.

Moment at GL (lb.-ft): Combined Offset Moment and Wind Moment in foot-pounds for the conductors in this entry.

% Of Total Moment: The percent of the Total Moment caused by the conductors in this entry.

The following is a list of the terminology used with respect to communication cables (FIGS. 66-71):

Communication Cables: Specific details about the Communication Cables. The loading details are not factored by the overload factors.

Qty: The number of Communication Cables attached at this height.

Attach Height (ft): The attachment height of the Communication Cables in feet.

Horiz. Offset (in): If the cable is not located at the pole or balanced by an equivalent conductor on the other side of the pole, this distance will account for the moment created by the weight of the cable. This distance is measured from the pole surface to the conductor perpendicular to the line-of-lead in inches.

Cable Dia (in): The outer diameter of the cable in inches.

Cable Weight (lbs.): Total cable weight in pounds without the overload factor.

Cable Tension (lbs.): This input is only required for angle structures. The value should approximate the design tension and the program will apply the Wire Tension Overload factor in pounds.

Left Span (ft): The length of the cable span in feet from the pole being analyzed to the pole on the left. For roadside poles, the left span is located as the observer looks toward the pole with the street beyond the pole.

Right Span (ft): The length of the cable span in feet from the pole being analyzed to the pole on the right. For roadside poles, the right span is located as the observer looks toward the pole with the street beyond the pole.

Left Angle (deg): The angle of the left span in degrees. A tangent structure will have zero for both the left and right angle. Consult the Directional Guide for orientation of the angles and wind direction (FIG. 69).

Right Angle (deg): The angle of the right span in degrees. A tangent structure will have zero for both the left and right angle. Consult the Directional Guide for orientation of the angles and wind direction (FIG. 69).

Cable Weight (lbs.): Total cable weight in pounds without the overload factor.

Ice Weight (lbs.): Weight of the ice in pounds on the cable without the overload factor.

Total Weight (lbs.): Total weight of the cable and ice in pounds if applicable without the overload factor.

The following terminology is used in the Summary Reports of FIGS. 82 and 83:

Wind Span (ft): The effective span exposed to the wind accounted by one-half of each span. If it is an angle structure, the program adjusts the length in feet of the resulting span that is perpendicular to the wind.

Weight Span (ft): The total span in feet for determining the conductor weight figured using one-half of each span regardless of the angle of the line.

Offset Moment (lb.-ft): Moment created by the distance that the weight of the cable is offset from the center of the pole without the overload factors in foot-pounds.

Wind Load (lbs.): Wind load on the quantity of cables in this entry without the overload factors in pounds.

Wind Moment (lb.-ft): Moment created by the wind load on the quantity of cables in this entry without the overload factors in foot-pounds.

Moment at GL (lb.-ft): Combined Offset Moment and Wind Moment for the cables in this entry in foot-pounds.

% Of Total Moment: The percent of the Total Moment caused by the cables in this entry.

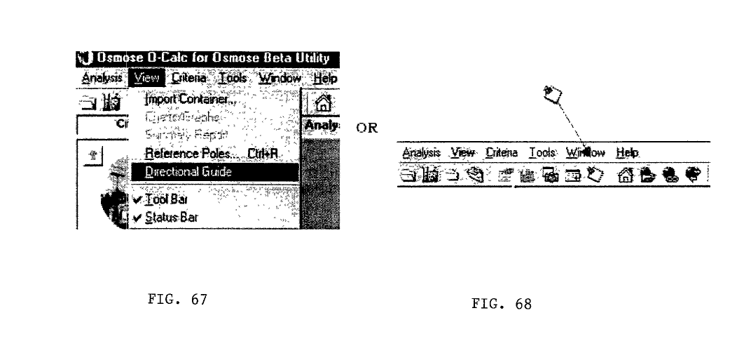

In FIG. 66, data is inputted for the “Left Span” and “Right Span” lengths, and associated “Left Angle” and “Right Angle” spans. The “Left Span” is the length of the conductor from the pole being analyzed to the pole on the left. Take for example the case of a roadside pole. The “Left Span” is length of the pole being analyzed to the pole on the left, when the observer looks at the pole with the street beyond the pole. The “Right Span” of the conductor is the length of the conductor from the pole being analyzed to the pole on the right, as the observer looks toward the pole with the street beyond the pole. Next, the user inputs the “Left Angle” and “Right Angle” data. The “Left Angle” is the angle of the “Left Span” in degrees, and the “Right Angle” is the angle of the “Right Span” in degrees. A tangent structure has zero for both “Left Angle” and “Right Angle” degrees. These spans and angles should represent the Line-of-Lead, shown in FIG. 69. FIGS. 67 and 68 show the drop down “View” menu and “Toolbar,” either of which the user may use to access the “Directional Guide” shown in FIG. 69.

FIG. 70 shows the input screen to “Add a Conductor.” The “Left Span” and “Right Span”, and respective “Left Angle” and “Right Angle” are input for the conductor too, as described above. The “Weight Span” (the total conductor weight, using one half the weight of each span regardless of the angle of the line) is input. The “Wind Span” (the effective span exposed to the wind accounted by one half of each span) is input. The type of conductor is selected from “Power,” “Communication,” “Drop,” and “Overlashed” (seen on the bottom left of FIG. 70). This selection determines what choices are available from the “Type” drop down menu in FIG. 70. The “Type” drop down menu access a databank loaded with different choices for conductors, drop lines, power lines, and overlashed lines. The user may select any of these, or may click on the “Facilities” box and this allows the user to add specifications for a completely new conductor to the databank.

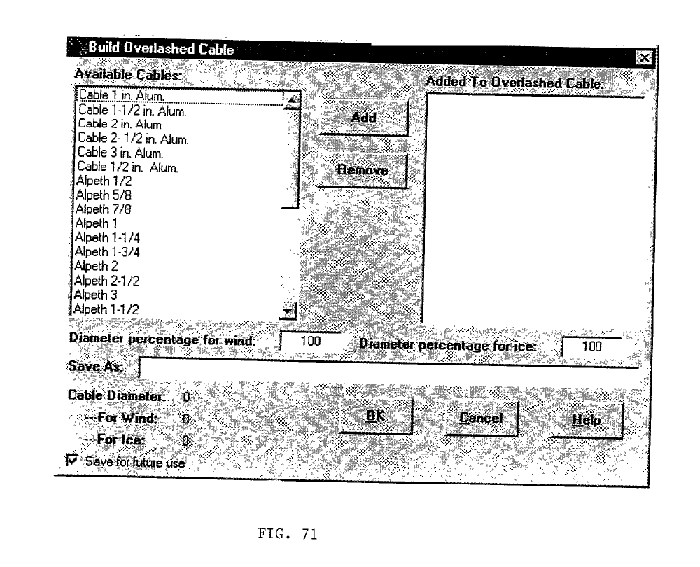

After selecting the “Type” of conductor in FIG. 70, the “Quantity”, “Attachment Height”, and “Horizontal Offset” data is input into the appropriated data entry boxes shown in FIG. 71. “Tension” need only be input into the dialog box for angle structures to account for the transverse component of the conductor tension. Once the this information is input in accordance with FIG. 71, the user may select “Add”, and the conductor is added to the pole. This procedure may be repeated to add additional conductors, and cable lines to the pole.

Service “Drops” (selected from the data input box in the lower left portion of the screen display in FIG. 70) may be added to the pole in a manner similar to the above described procedure for adding “Conductors”. The conductor “Type,” “Quantity,” “Attachment Height,” “Horizontal Offset,” and “Tension” are entered via the “Add Conductor” input box, the typical tension for a slack span being about 40 lbs. to 50 lbs. Midspan drops may also be input. Both the span and tension of the midspan drop are applied as a ratio of the distance from the pole being analyzed and the adjacent pole. The span length (or tension) of the drop is determined by multiplying the total drop span length (or tension) times one minus the ratio of the distance of the midspan attachment to the total span length between the poles. For example, assume the midspan drop is a total length of 90 feet and a tension of 100 lbs. that is attached 60 feet from the pole being analyzed. The total distance between the poles is 180 feet. Applying the formula yields 60 for the length of the span and 66.7 lbs. for the tension. These numbers are then be used in the analysis.

Another feature of the computer software program is the “Build Overlashed Cable” tool, shown in FIGS. 70 and 71. This tool allows the user, in the event a particular overlashed cable is not in the conductor databank, to click on the “Build Overlashed Cable” tool and build the desired cable. The user need only select available the desired cables stored in the databanks, and add the cables the cables together by highlighting the cable to be added, and then selecting the “Add” feature. The grouping of the cables added by the individual is listed in the “Added To Overlashed Cable” box in FIG. 71. The user may set a separate percentage value that is applied to the total diameter of the stacked cables for both wind and ice loading, for example, the user may leave the diameter at 100% for the wind loading, but reduce that diameter to 80% for computing the ice loading. The user may then save this overlashed cable in the overlashed cable databank, and then add this overlashed cable to the pole.

The software program has the additional functionality, such that the user may change the input “Conductor” data for conductors already added to the pole, and also delete conductors. After the conductors are entered, the user clicks on the “Apply Conductor” button in FIG. 66, thus requesting the computer processor to update and process all of the input conductor data. This also automatically pulls up the next data entry page, the “Transformer” input data page.

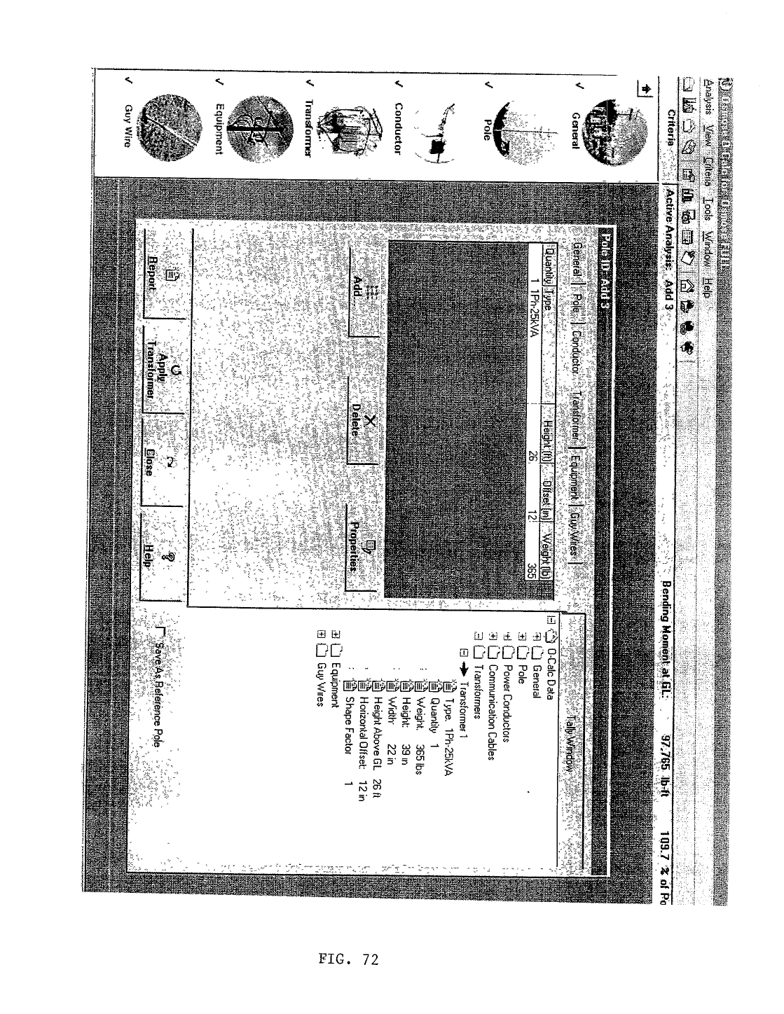

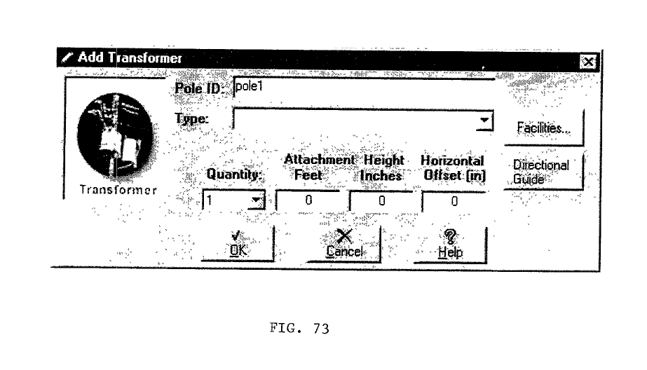

The following is a list of the terminology used throughout the “Transformer” data input pages generated by the computer software program being executed on the computer, seen in FIGS. 72 and 73.

Transformers: Specific details about the Transformers. The loading details are not factored by the overload factors.

Qty: The number of Transformers attached at this height.

Attach Height (ft): The attachment height of the Transformers in feet.

Horiz Offset (in): The distance perpendicular to the line-of-lead from the center of the pole to the center of the transformer in inches.

Unit Weight (lbs.): The weight of one transformer of the quantity in this entry in pounds.

Unit Height (in): The height of each transformer in this entry in inches.

Unit Width (in): The width of each transformer in this entry in inches.

Unit Area (in²): The area of each transformer in this entry shown in square inches.

Unit Area (ft²): The area of each transformer in this entry shown in square feet.

Shape Factor (lbs.): This factor is used in the wind load calculations and is 1.0 for round objects and 1.6 for objects with a flat surface.

The following terminology appears in the Summary Report in FIGS. 82 and 83.

Offset Moment (lb.-ft): Moment created by the distance that the weight of the conductor is offset from the center of the pole without the overload factors in foot-pounds.

Wind Load (lbs.): Wind load on the quantity of transformers in this entry without the overload factors in pounds.

Wind Moment (lb.-ft): Moment created by the wind load on the quantity of transformers in this entry without the overload factors in foot-pounds.

Moment at GL (lb.-ft): Combined Offset Moment and Wind Moment for the transformers in this entry in foot-pounds.

% Of Total Moment: The percent of the Total Moment caused by the transformers in this entry.

To input data for a transformer the user selects the “Add” feature in FIG. 72 and inputs data in the appropriate fields in FIG. 73. The type of transformer is selected from “Type” drop down box in FIG. 73. If the type of desired transformer is not found in the drop box, the facilities feature may be selected, and this allows the user to add a transformer to the database input the desired specifications for the transformer. Then the user next inputs data for the “Quantity”, “Attachment Height”, and “Horizontal Offset” for the transformer. The “Horizontal Offset” is the distance perpendicular to the Line-of-Lead from the center of the pole to the to the center of the transformer. To change the properties of a transformer that has already been inputted into the computer, the transformer is first highlighted by clicking on it from the transformer list. Next, clicking on the “Properties” button causes the “Transformer Properties Window” to appear. The user then makes the desired changes and clicks on the “Apply” button, and the data for the transformer is updated. To delete a transformer requires highlighting the transformer, and clicking on the “Delete” button. Last, click on the “Apply” transformer button to cause the computer to process the transformer data.

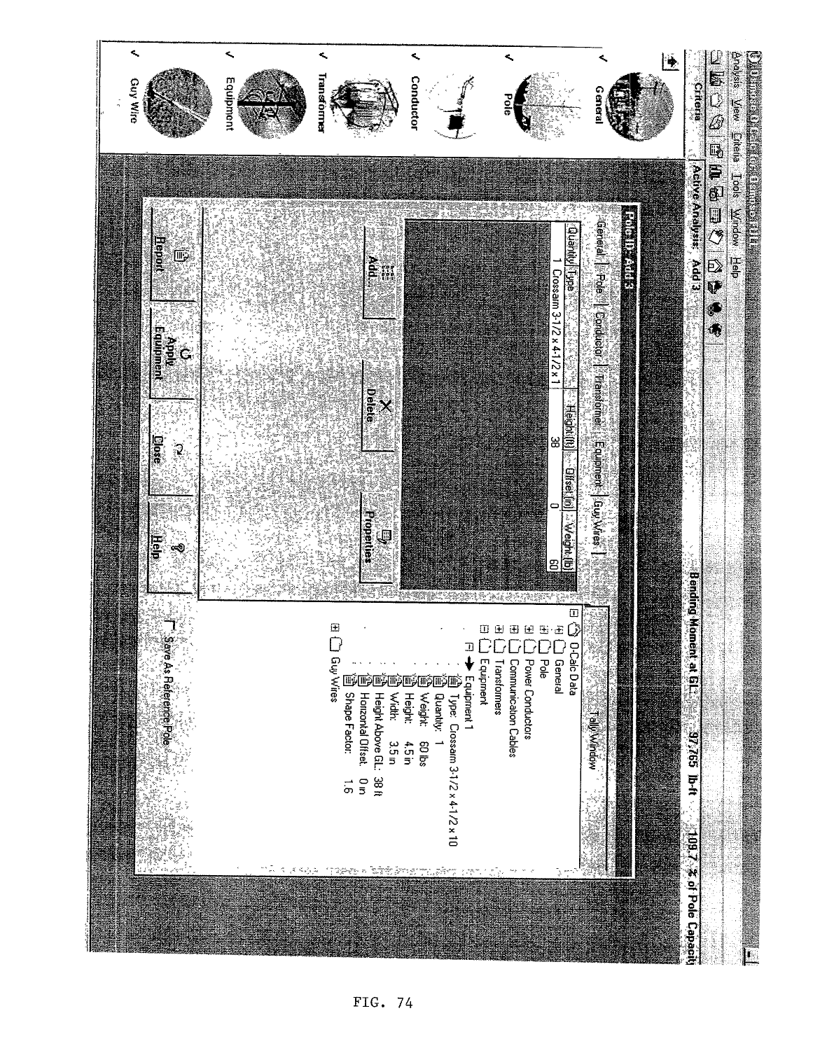

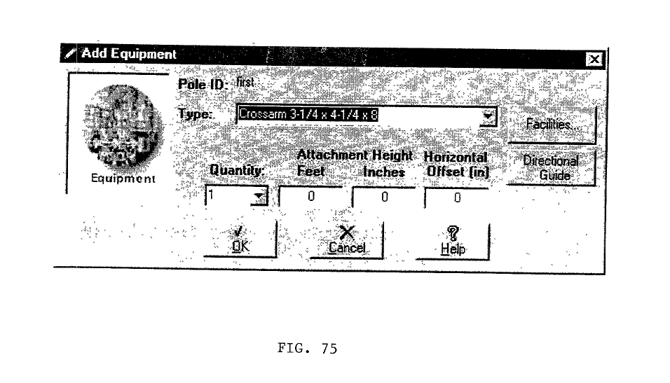

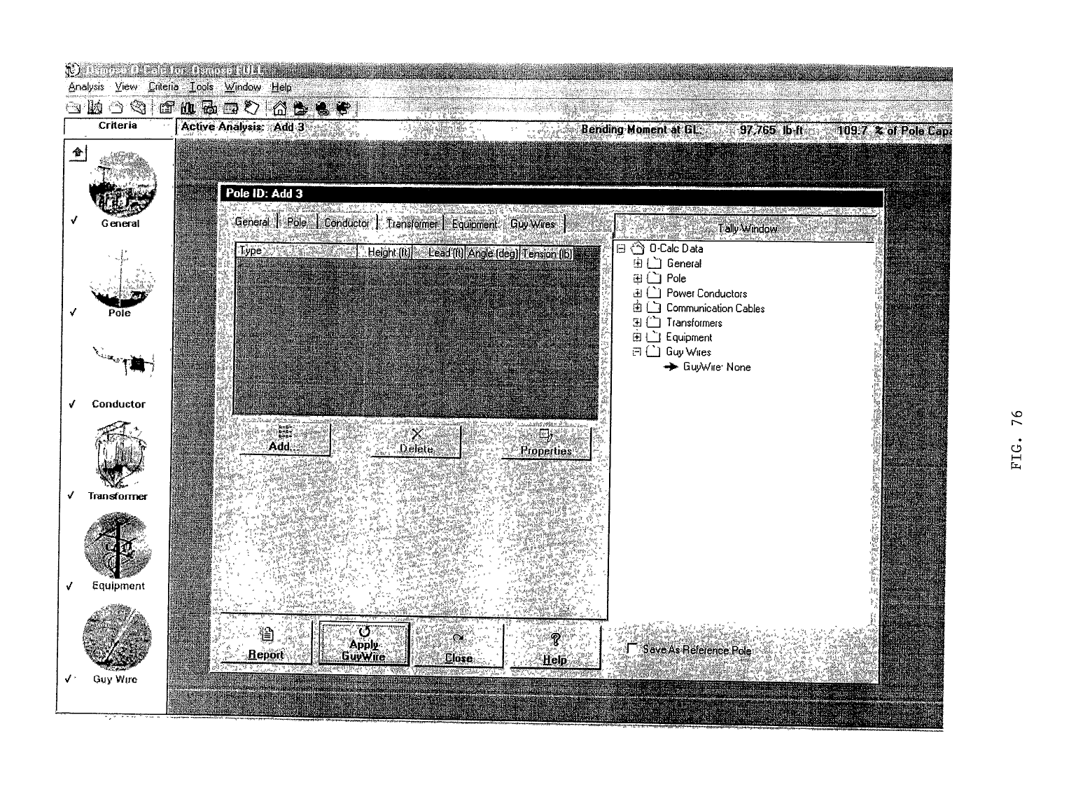

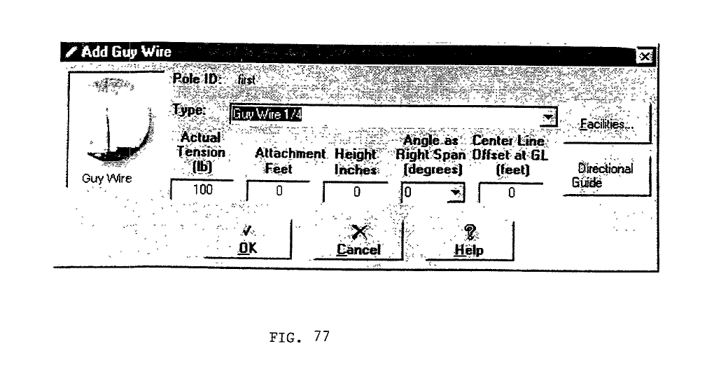

Next, the “Equipment Data Input Page” screen display is provided that allows for the input of data pertaining to equipment loading on the pole, such as street lights. FIGS. 74 and 75 show the data input screen displays for the equipment, the displays generated by the computer software program being executed on the computer.

The following is a list of the terminology used therein.

Equipment: Specific details about the Equipment. The loading details are not factored by the overload factors.

Qty: The number of this equipment item attached at this height.

Attach Height (ft): The attachment height of the Equipment in feet.

Horiz. Offset (in): The distance perpendicular to the line-of-lead from the center of the pole to the center of the equipment in inches.

Unit Weight (lbs.): The weight of one unit of the equipment in this entry in pounds.

Unit Height (in): The height of the equipment in this entry in inches.

Unit Width (in): The width of the equipment in this entry in inches.

Unit Area (in²): The area of the equipment in this entry shown in square inches.

Unit Area (ft²). The area of the equipment in this entry shown in square feet.

Shape Factor (lbs.): This factor is used in the wind load calculations and is 1.0 for round objects and 1.6 for objects with a flat surface.

The following terminology appears in the Summary Report:

Offset Moment (lb.-ft): Moment created by the distance that the weight of the equipment is offset from the center of the pole without the overload factors in foot-pounds.

Wind Load (lbs.): Wind load on the equipment in this entry without the overload factors in pounds.

Wind Moment (lb.-ft): Moment created by the wind load on the equipment in this entry without the overload factors in foot-pounds.

Moment at GL (lb.-ft): Combined Offset Moment and Wind Moment for the equipment in this entry in foot-pounds.

% Of Total Moment: The percent of the Total Moment caused by the equipment in this entry.

The tab for this feature appears elevated in FIG. 74. The user selects the “Add” button, and the “Add Equipment” window appears. The “Type” drop down box is selected, and this allows the user to select data pertaining to equipment already existing in the software program databanks. The user may also select the “Add” feature and add equipment with new specifications, and immediately store this information in a databank. The specifications for this equipment data may then be stored for future use. After “Equipment Type” is selected, the user inputs the information for “Quantity,” “Attachment Height,” and “Horizontal Offset.” Height may be input in feet and inches, or feet and decimals. The “Horizontal Offset” is the distance perpendicular to the Line-of-Lead from the center of the pole to the center of the equipment. To make changes to a piece of equipment, the piece of equipment is highlighted by clicking on that item, and then the “Properties” button is clicked, and the equipment properties window appears. The changes may then be made by the user, and the “Apply” button is then clicked. The changes are thus made. To delete items requires highlighting the item and clicking “Delete” button in FIG. 74. Once all the data for the equipment is entered, the “Apply Button” is clicked, and causes the software to processes the data, and also brings up the next data input page for “Guy Wires”.

The “Guy Wire” data input page is shown in FIGS. 76 and 77. FIG. 76 shows the “Guy Wire” tab raised, indicating that screen display is ready for the data inputs.

The following are definitions are used in conjunction with the data input page for guy wires:

Guy Wire: Specific details about the Guy Wires. The loading details are not factored by the overload factors.

Attach Height (ft): The attachment height of the Guy Wire in feet.

Pole CL to Anchor: The distance from the pole to the anchor.

Guy Wire Angle (deg): Orientation of the Guy Wire in reference to the line-of-lead, which is expressed using the Right Span orientations in the Directional Guide.

Angle from GL (deg): Angle of the Guy Wire to the ground in degrees.

Tension Force (lbs.): Tension in the Guy Wire in pounds.

Vertical Force (lbs.): Vertical component of the tension in the Guy Wire in pounds. Positive tension can be applied to model pushes and pulls.

Transverse Force (lbs.): Transverse horizontal component of the tension in the Guy Wire in pounds.

In Line Force (lbs.): Longitudinal horizontal component of the tension in the Guy Wire in pounds.

The following terminology is used in the Summary Report:

Moment at GL (lb.-ft): Moment at ground line created by tension in the Guy Wire in foot-pounds.

% of Total Moment: The percent of Total Moment caused by the Guy Wire in this entry.

To input data for guy wires, the “Add” button is depressed in FIG. 76, and the “Add Guy Wire” window appears. It is noted that angles for guy wires are referenced from the right span. The “Type” of guy wire is selected from the drop box (FIG. 77), and the “Guy Wire Facilities Window” shows the specifications for guy wires currently stored in the computerized databanks. The user may click on “Add” and input new specifications for the “Guy wire,” and click “OK” (FIG. 77) and the new guy wire specifications are added to the guy wire databank.

Once the “Guy Wire Type” is input into the computer, data is input for the “Tension”, “Attachment Height”, “Angle as Right Span”, and “Center Line Offset at Ground Line,” as seen in FIG. 77. Attachment height may be in feet and inches, or feet with decimals.

To make changes to the “Guy Wire,” the user selects the “Properties Button” (FIG. 76), and the “Guy Wire Properties Window” appears, and the user may make changes to the guy wire properties, and then select the “Apply Button” to complete the changes. To delete a guy wire, the user need only highlight the “Guy wire,” and click “Delete.”

Once all the guy wire data is input, clicking on the “Apply Guy Wire” button in FIG. 76 causes all the input data to be processed. This also send the user back to the “General” data input page, and the computer software program is ready to produce a “Summary Report.”This computer software program generates this report when the user selects the “Report Button” shown in FIG. 48. Examples of an output “Summary Reports” are seen in FIGS. 82 and 83.

The software program allows the user to create a “Reference Analysis” for situations wherein a number of poles with similar construction are going to be analyzed. As shown in FIG. 48, a “Save as a Reference Pole” check box appears below the “Tally” window. This check box also appears in FIGS. 65, 66, 72, 74, and 76. The user may click on the check box in any of these data input pages in order to save the pole data as a “Reference Pole.” Any analysis may be saved as a “Reference Pole”, and the “Reference Pole” then serves as a template to which more cables, wires, conductors, and equipment can be added.

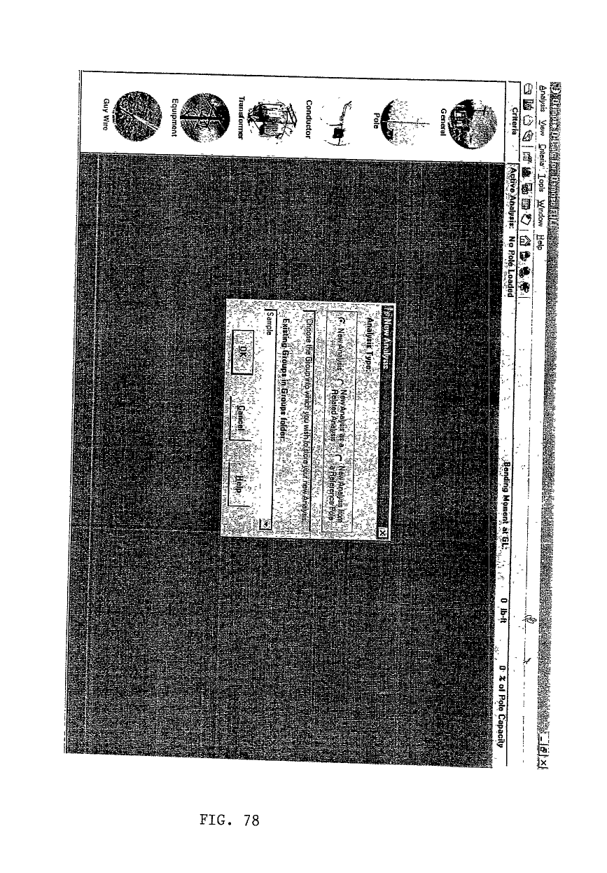

A “New Analysis” can be created by using a previously created “Reference Pole” as a template in the following manner. First, the “Analysis” drop down menu is selected (FIG. 50), and “New Analysis” is clicked. This brings up the screen display shown in FIG. 78. Then the “New Analysis from a Reference Analysis Button” is selected (the button for this feature seen in FIGS. 62 and 78), and the user selects the group in which the “New Analysis” is to be saved. Clicking “OK” and the “Reference Pole” window appears. The user then selects the desired “Reference Pole” and clicks “OK”, and enters the “Pole ID”, and clicks save. The user may then proceed to the “Input Data Pages” and continue with the analysis. After the data is inputted, the “Refresh Button” is clicked, and this causes a new “Summary Report” (described in detail below) to be generated. The “Analysis” is saved to the group specified by the user, and the “Reference Pole” returns to its original group unchanged. FIG. 51 shows that pull down menu that allow the user to view the “Reference Poles” stored in databanks. This, feature thus allows for the rapid analysis of a plurality of poles having similar construction, by eliminating the need to have pole data repeatedly input into the databanks.

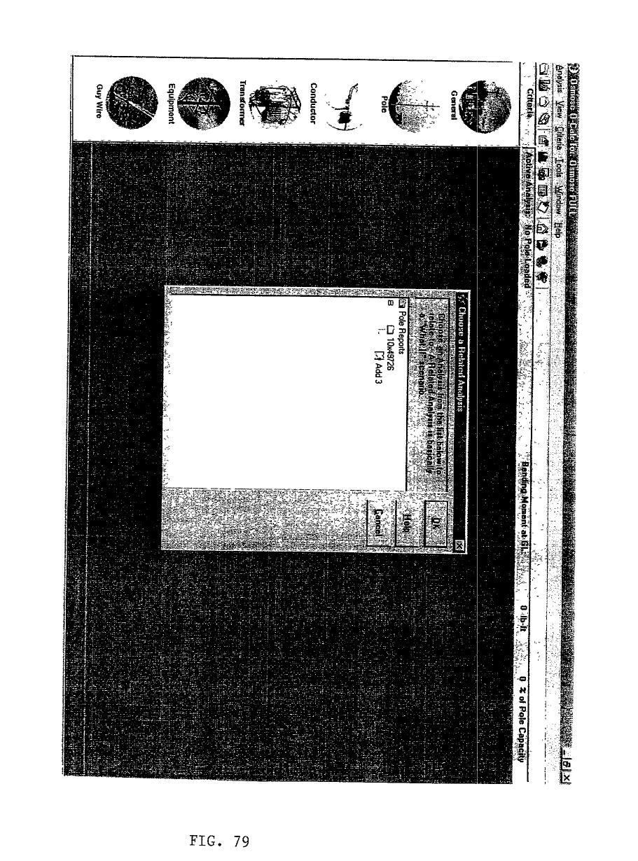

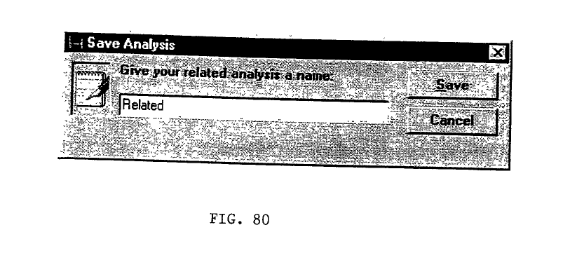

The system and methodology of the present invention also provide a “What If” feature that allows the user to alter pole loading and assess the pole anew. When a pole “Analysis” is saved, it represents the pole as it exists in the field, and is the labeled the “Parent Analysis.” A “Related Pole” analysis opens the existing pole “Analysis” and allows the user to add any desired loads to the poll, whether they be from conductors, transformers, and equipment. These loads are the “What If's,” that is “What If” the pole was loaded in different way, what would be the resultant loads and would they be acceptable, or would they cause the pole to become overloaded. To perform a “What if” scenario analysis, the user selects the “New Analysis as a Related Analysis” button, as shown in FIG. 78. The user selects a group and clicks “OK”, and that causes the computer to display the “Choose a Related Analysis,” window as seen in FIG. 79. The user highlights the desired “Analysis”, and the “Save Analysis” window appears (FIG. 80), and the user enters and “Saves” a name for the “Related Analysis.”

The user may then make any additions or changes and click the “Refresh” button, and a new “Summary Report” is generated. As shown in FIG. 79, the report is identified with the name of the “Related Analysis.” The listing of the “Analyses” within the “Group” show the “Related Analyses” listed under the “Parent Analysis.”

The “Summary” is generated when the computer software program is executed and determines the loading on the pole from the pole loading data inputs. As seen in FIGS. 82 and 83, a great deal of information is provided on a single screen display. The summary report may be printed on a single sheet of paper. Again it is noted all of the output values in FIGS. 82 and 83 are for illustrative purposes, and other data inputs will cause different output to be generated by the computer software program. After all the data is inputted into the computer, the user need only click on the “Report” button seen in the bottom of the screen display in FIG. 48, and the software program generates and displays a “Summary Report” of the pole “Analysis”. The “Summary Report” may be embodied as color coded, for example, the blue text items are input data from the user, while black text items are numbers generated caused to be generated by the software program running on the computer. Such color coding facilitates using the “Summary Report,” and is useful to field workers. The “Summary Report” may be saved, exported by email or other suitable means, or printed on tangible media.

The following is a list of the terminology used in the “Summary Reports”, shown in FIG. 82 and 83.

Transverse Load Summary: Transverse Load Summary by Groups of attachments including Power Conductors, Communication Cables, Pole Transformers, Equipment and Guy Wires.

Transverse Load for Power Conductors (lb.): The total transverse load in pounds on the Power Conductors including wind and wire tension multiplied by the overload factors.

Transverse Load for Comm Cables (lb.): The total transverse load in pounds on the Communication Cables including wind and wire tension multiplied by the overload factors.

Transverse Load for Pole (lb.): The total transverse wind load in pounds on the surface area of the pole above ground multiplied by the overload factor.

Transverse Load for Transformers (lb.) The total transverse wind loading pounds on the Transformers including overload factors.

Transverse Load for Equipment (lb.): The total transverse wind load in pounds on the Equipment including overload factors.

Transverse Load for Guy Wires (lb.): The total transverse load caused by the tension in Guy Wires.

Percent of Total Load for Power Conductors (%): The percent of the total transverse load resulting from the Power Conductors.

Percent of Total Load for Comm Cables (%): The percent of the total transverse load resulting from the Communication Cables.

Percent of Total Load for Pole (%): The percent of the total transverse load resulting from the wind load on the Pole itself.

Percent of Total Load for Transformers (%): The percent of the total transverse load resulting form the Transformers.

Percent of Total Load for Equipment (%): The percent of the total transverse load resulting from the Equipment.

Percent of Total Load for Guy Wires (%): The percent of the total transverse load resulting from the Guy Wires.

Bending Moment at GL for Power Conductors (ft-lb.): The load components from transverse wind, offset and wire tension on each conductor is multiplied by the attachment height above ground and the overload factor to determine the total bending moment at the groundline for all Power Conductors.

Bending Moment at GL for Comm Cables (ft-lb.): The load components from transverse wind, offset and wire tension on each cable is multiplied by the attachment height above ground and the overload factor to determine the total bending moment at the groundline for all Communication Cables.

Bending Moment at GL for Pole (ft-lb.): The transverse wind load on the surface area of the pole is multiplied by the height of the pole center area above ground and the transverse wind Overload Capacity Factor to determine the resulting bending moment at the groundline.

Bending Moment at GL for Transformers (ft-lb.): The load components from transverse wind and offset on each transformer is multiplied by the attachment height above ground and the overload factor to determine the total bending moment at the groundline for all Transformers.

Bending Moment at GL for Equipment (ft-lb.): The load components from transverse wind and offset on each equipment item is multiplied by the attachment height above ground and the overload factors to determine the total bending moment at the groundline for all Equipment.

Bending Moment at GL for Guy Wires (ft-lb.): The bending moment at the groundline induced by the transverse component of the guy wire tension multiplied by the attachment height above ground.

Percent of Total Moment for Power Conductors (%) The percent of the total bending moment at the groundline resulting from the Power Conductors.

Percent of Total Moment for Comm Cables (%): The percent of the total bending moment at the groundline resulting from the Communication Cables.

Percent of Total Moment for Pole (%): The percent of the total bending moment at the groundline resulting from the wind load on the Pole itself.

Percent of Total Moment for Transformers (%): The percent of the total bending moment at the groundline resulting from the Transformers.

Percent of Total Moment for Equipment (%): The percent of the total bending moment at the groundline resulting from the Equipment.

Percent of Total Moment for Guy Wires (%): The percent of the total bending moment at the groundline from the Guy Wires.

Percent of Pole Capacity for Power Conductors (%): The percent of pole bending capacity at the groundline that the moment resulting from the Power Conductors equates to.

Percent of Pole Capacity for Comm Cables (W): The percent of pole bending capacity at the groundline that the moment resulting from the Communication Cables equates to.

Percent of Pole Capacity for Pole (%): The percent of pole bending capacity at the groundline that the moment resulting from the wind load on the pole itself equates to.

Percent of Pole Capacity for Transformers (%): The percent of pole bending capacity at the groundline that the moment resulting from the Transformers equates to.

Percent of Pole Capacity for Equipment (%): The percent of pole bending capacity at the groundline that the moment resulting from the Equipment equates to.

Percent of Pole Capacity for Guy Wires (%): The percent of pole bending capacity at the groundline that the moment resulting from the Guy Wires equates to.

Bending and vertical stress summary.

Bending Stress at GL for Power Conductors (psi): The maximum bending stress in the groundline cross section of the pole created by the bending moment at the groundline from all of the Power Conductors.

Bending Stress at GL for Comm Cables (psi-pounds per square inch): The maximum bending stress in the groundline cross section of the pole created by the bending moment at the groundline from all of the Communications Cables.

Bending Stress at GL for Pole (psi): The maximum bending stress in the groundline cross section of the pole created by the bending moment at the groundline resulting from the wind load on the pole surface area.

Bending Stress at GL for Transformers (psi): The maximum bending stress in the groundline cross section of the pole created by the bending moment from all of the transformers.

Bending Stress at GL for Equipment (psi): The maximum bending stress in the groundline cross section of the pole created by the bending moment from all of the equipment.

Bending Stress at GL for Guy Wires (psi): The maximum bending stress in the groundline cross section of the pole created by the bending moment from the guy wires.

Vertical Load for Power Conductors (lb.): The vertical load resulting from the weight of the Power Conductors and any applied ice multiplied by the vertical overload capacity factor.

Vertical Load for Comm Cables (lb.): The vertical load resulting from the weight of the Communication Cables and any applied ice multiplied by the vertical overload capacity factor.

Vertical Load for Pole (lb.): The vertical load resulting from the weight of the Pole above ground multiplied by the vertical overload capacity factor.

Vertical Load for Transformers (lb.): The vertical load resulting from the weight of the Transformers multiplied by the vertical overload capacity factor.

Vertical Load for Equipment (lb.): The vertical load resulting from the weight of the Equipment multiplied by the vertical overload capacity factor.

Vertical Load for Guy Wires (lb.): The vertical load resulting from the tension in the Guy Wire.

Vertical Stress at GL for Power Conductors (psi): The vertical weight of the Power Conductors divided by the cross sectional area of the pole at the groundline (P/A) in pounds per square inch.

Vertical Stress at GL for Comm Cables (psi): The vertical weight of the Communication Cables divided by the cross sectional area of the pole at the groundline (P/A) in pounds per square inch.

Vertical Stress at GL for Pole (psi): The vertical weight of the Pole above ground multiplied by the Overload Capacity Factor and divided by the cross sectional area of the pole at the groundline (P/A) in pounds per square inch.

Vertical Stress at GL for Transformers (psi): The vertical weight of the Transformers multiplied by the Overload Capacity Factor and divided by the cross sectional area of the pole at the groundline (P/A) in pounds per square inch.

Vertical Stress at GL for Equipment (psi): The vertical weight of the Equipment divided by the cross sectional area of the pole at the groundline (P/A) in pounds per square inch.

Vertical Stress at GL for Guy Wires (psi): The vertical load of the Guy Wires divided by the cross sectional area of the pole at the groundline (P/A) in pounds per square inch.

Total Stress at GL for Power Conductors (psi): The total compressive stress at the groundline resulting from the bending moment and the vertical load of the Power Conductors.

Total Stress at GL for Comm Cables (psi): The total compressive stress at the groundline resulting from the bending moment and the vertical load of the Communication Cables.

Total Stress at GL for Pole (psi): The total compressive stress at the groundline resulting from the bending moment and the vertical load of the Pole.

Total Stress at GL for Transformers (psi): The total compressive stress at the groundline resulting from the bending moment and the vertical load of the Transformers.

Total Stress at GL for Equipment (psi): The total compressive stress at the groundline resulting from the bending moment and the vertical load of the Equipment.

Total Stress at GL for Guy Wires (psi): The total compressive stress at the groundline resulting from the bending moment and the vertical load of the Guy Wire.

Percent of Pole Capacity for Power Conductors (%) The percent of pole bending capacity that the total groundline stress from the Power Conductors equates to.

Percent of Pole Capacity for Comm Cables (%): The percent of pole bending capacity that the total groundline stress from the Communication Cables equates to.

Percent of Pole Capacity for Pole (%): The percent of pole bending capacity that the total groundline stress from the Pole itself equates to.

Percent of Pole Capacity for Transformers (W): The percent of pole bending capacity that the total groundline stress from the Transformers equates to.

Percent of Pole Capacity for Equipment (%): The percent of pole bending capacity that the total groundline stress from the Equipment equates to.

Percent of Pole Capacity for Guy Wires (%): The percent of pole bending capacity that the total groundline stress from the Guy Wires equates to.

Vertical Load Summary of terms

Vertical Load Summary: Summary of the vertical buckling analysis using Euler's formula.

Buckling Constant: The constant that describes the end conditions of the column. This may be 2.0 for anguid structures and 0.7 for guyed structures.

Buckling Column Height (ft): The height of the column to be used in the buckling analysis.

Buckling Section Height(% Col. HGM): The percentage of the column height above ground where that diameter is used as the constant diameter for the full height of the column.

Buckling Section Diameter (in): The diameter of the pole at the specified percent of the column height above ground.

Min. Buckling Diameter at GL (in): The minimum diameter required at the groundline to resist the existing buckling load.

Actual Diameter at Tip (in): The diameter of the pole at the tip.

Actual Diameter at GL (in): The actual diameter of the pole at the groundline.

Buckling Load Capacity at Height (lb.): The factored buckling load capacity of the pole at the column height.

Buckling Load Applied at a Height (lb.): The actual factored equivalent buckling load applied at the column height.

Buckling Load Margin of Safety: The ratio of the pole buckling capacity to the buckling load applied minus 1. This number must be greater than zero for the pole to meet code requirements to resist buckling.

The “Summary Report” shows the output results from the computer executable software program executed on the input loading data. The format of the summary report allows a field worker to understand loading on a pole even though the worker may have no significant skills in engineering or mathematics. In other words, the field worker can use the program by inputting the loading observed in the field, and quickly access if a pole is able to withstand the loads being imposed on it. For example, in FIG. 82, given the input data as shown, 90.1% of the pole's transverse load capacity is being used, with 9.9% in reserve, and 91% of the pole's stress strength is being utilized with 9.0% in reserve. Under the vertical load summary, the buckling load margin of safety is 1.86, which since it is greater than zero indicates the pole will not readily fail due to buckling. From this a user is provided with numbers that show the pole will not fail. FIGS. 82a-82f show the graphical outputs generated by the computer software program, given the loading shown in FIG. 82. FIG. 82a shows the graph of the pole height versus horizontal shear load, FIG. 82b shows pole height versus bending moment, FIG. 82c shows pole height versus compressive stress, FIG. 82d shows pole height versus deflection, FIG. 82e shows component moments as a percentage of the total moment, and FIG. 82f shows component moments as a percentage of pole capacity at groundline. These graphs may be accessed as shown in the pull down menu in FIG. 51, and may be printed, exported, and/or saved for future use, or emailed to another user.

The analysis for the pole of FIG. 82 was for an underloaded pole. Turning now to FIGS. 83, 83a-83f, shown therein is a pole that is overloaded, that is the loading on the pole exceeds safety standards. FIG. 83 shows the loading summary report for an overloaded pole. In this scenario, 109.7% of the pole's transverse load capacity is being used, with −9.7% in reserve, and 110.8% of the pole's stress strength is being utilized with −10.8% in reserve. Under the vertical load summary, the buckling load margin of safety is 1.48, which since it is greater than zero indicates the pole will not readily fail due to buckling. The field worker can quickly assess that since the percent of pole capacity is a negative number, the pole is overloaded. FIG. 83a shows pole height versus horizontal shear load, FIG. 83b shows pole height versus bending moment, FIG. 83c shows pole height versus compressive stress, FIG. 83d shows pole height versus deflection, FIG. 83e shows component moments as a percentage of the total moment, and FIG. 83f shows component moments as a percentage of pole capacity at groundline

Hence, the present invention provides an easy to use methodology and computer software program, that generates rapid and accurate pole loading analyses. Additionally, since the software program stores the input data in databanks, and gives each pole its own identification, as described above, pole information is conveniently saved for future reference, thus eliminating the time consuming practice of having to reenter pole data every time a pole is analyzed and also allows calculations to made from the stored data at more convenient locations, such as indoor offices. Further, the computer program allows the user to mover freely between the data input pages at any time so that input data may be readily altered.

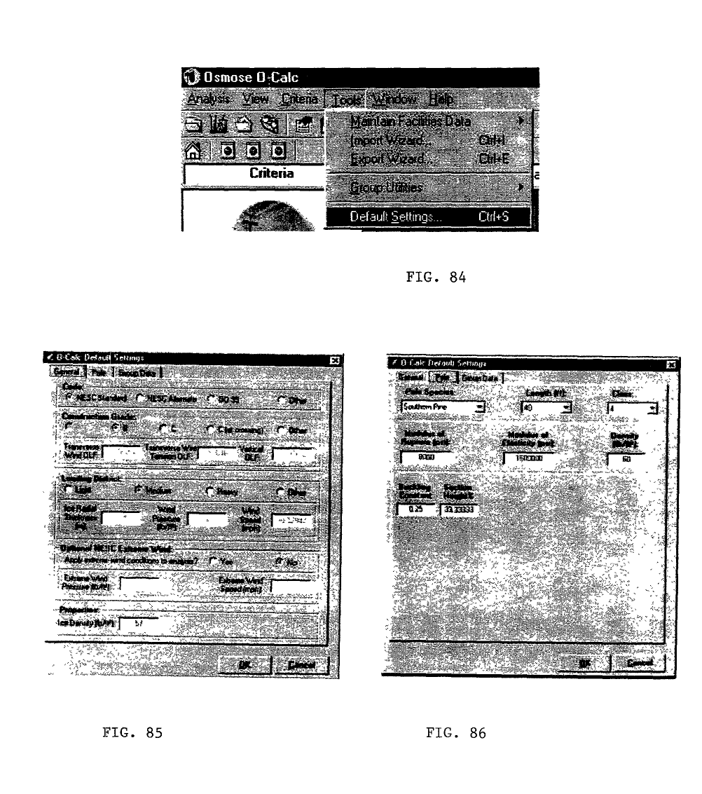

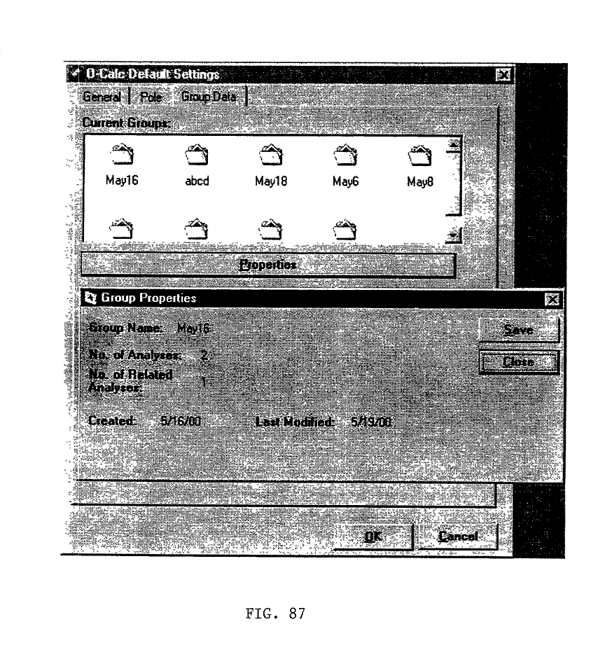

The software default settings may be changed on the data input screens by selecting the “Tools” drop down menu, seen in FIG. 84, and selecting the “Default Settings” option. This allows access to the “General” (FIG. 85) and “Pole” (FIG. 86) data defaults, and “Group Data” (FIG. 87) The user may change and save new “Default Settings” for the “General” and “Pole” data. As described above, the preset defaults save the user time, as this default data does not need to be reentered for every new pole analysis, and this avoids the errors associated with manually inputting default data.

On the “Group Data” page, all of the group analyses are displayed as icons. Highlighting one and clicking on the “Properties” button pulls up the “Group Properties” box, seen in FIG. 87. Displayed in this box is group information, and an option to select a location to create a backup copy of the group.

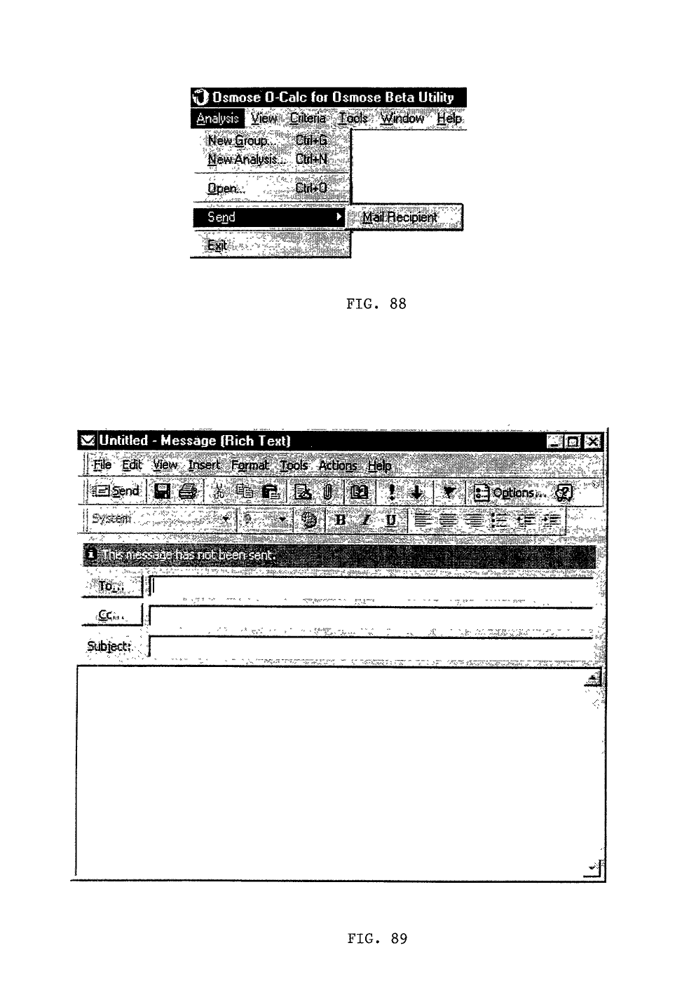

FIGS. 88 and 89 show how access is available to email while using the system, methodology, and computer program product described herein.

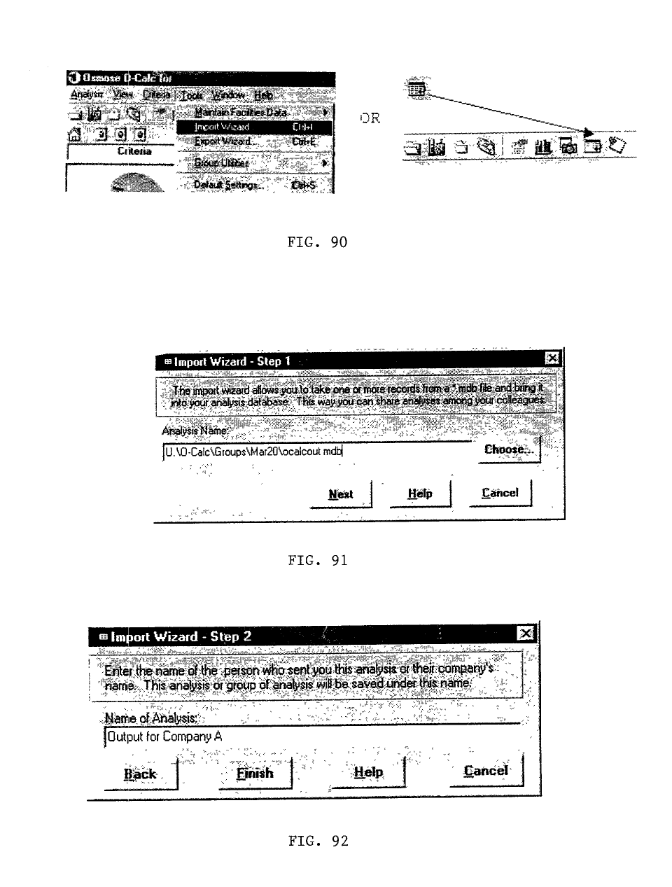

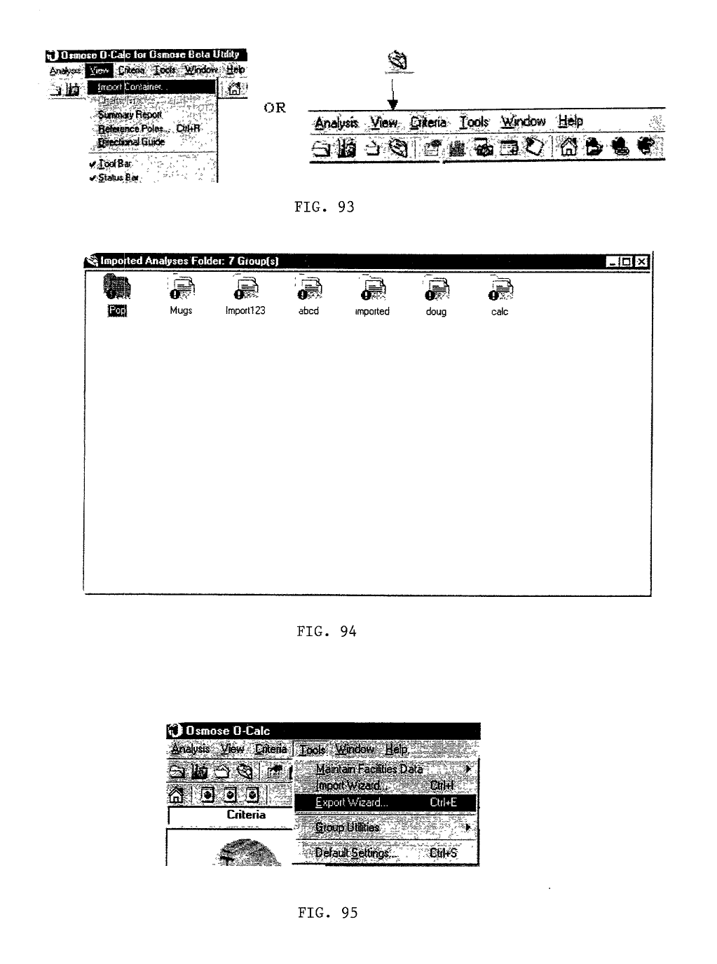

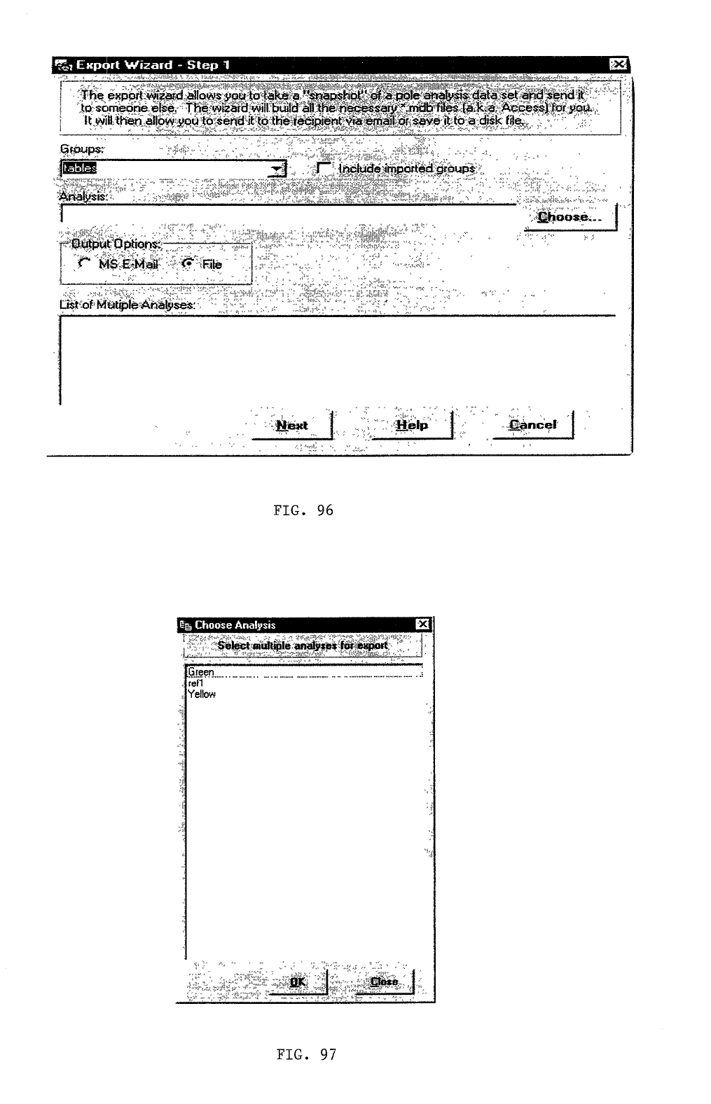

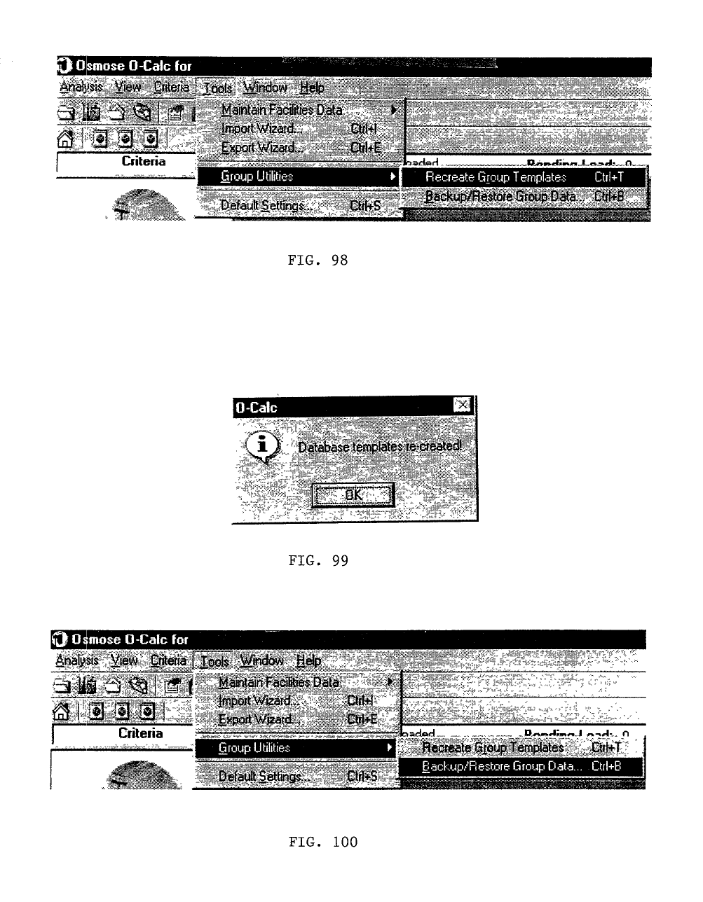

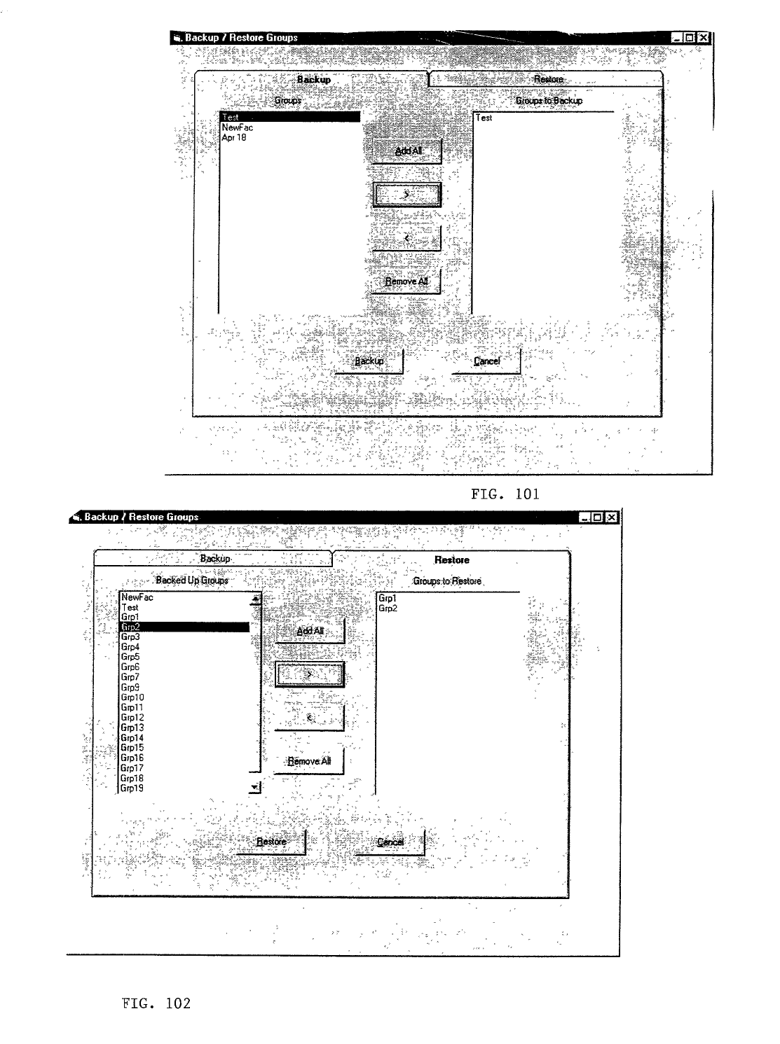

One user may also send an analysis, for example a summary report, to another user by way of email, or may send a disk with the pole analysis saved therein to another user. For example, in one embodiment, an import tool may be used to make incoming analyses viewable on a computer. This is shown in FIGS. 90-92. Once imported, the analyses may be stored in the “Import Container,” as shown in FIGS. 93 and 95. If on the other hand the user desires to send an analysis to another user, by email, the export tool feature may be used as shown in FIGS. 95-97. Import and export tools for sending email files is well known to those of ordinary skill in the art. Also, the software program is provided with a “Recreate Group Template” feature that allows the group templates to be recreated, as shown in FIGS. 98 and 99. To “Backup” or “Restore” any groups, the methods shown in FIGS. 100-102 may be implemented.

Flowcharts

FIGS. 64, 81, 103-106 show the flowcharts illustrating the operation of the computer software program utilized in the method, system, and computer program product described above.

The symbols appearing in the flowcharts are as follows:

A rectangle with rounded corners means the start or end of a process terminal.

A diamond means a decision.

A half cylindrical shell means a database structure.

A rectangle with one side longer than the other means manual data input is called for.

A rectangle means a start of a process, such as analyzing data, or performing calculations, for example, to generate a summary report.

A rounded cornered rectangle that points to the left is a function.

A six sided figure means data preparation.

FIG. 64 the operational flowchart of the software for the general data page shown in FIG. The general data input page flowcharts are shown in FIG. 64. The flow begins with the general start end terminal 1, and then a decision is made with respect to the safety code 2 to be used in the analysis. Stored in the databases indicated by reference numbers 3 and 4, are the NESC and GO95 codes, allowing for the retrieval of the overload factors (OLF's). As discussed above, overload factors are load multipliers as required by the applicable safety codes. If the “other” 7 option is selected, the OLF's are input manually by the user.

Selecting the flow of an NESC 3 analysis proceeds with selecting the construction grade 5, that may be manually input 7, or retrieved from an OLF database 13. If extreme wind 15 is selected 14, the OLF's are retrieved from the database and the wind speed or pressure is manually input 16. If extreme wind 15 is not selected, the loading district 17 is selected. Ice and wind data is retrieved 18 and the ice density and wind direction is manually input 12. The input data is saved 19. Similarly, if the building code 2 selected is for GO95, the construction grade 6 is selected, and the OLF's are retrieved from a database 8. The loading district 9 is selected, and ice and wind loading is manually input 12, and the input data is saved 19. The flow from the code 2, to input OLF's 7, to input ice and wind 10, to input ice density and wind direction 12, to save 19 illustrates the operation of the software when the user manually inputs data.

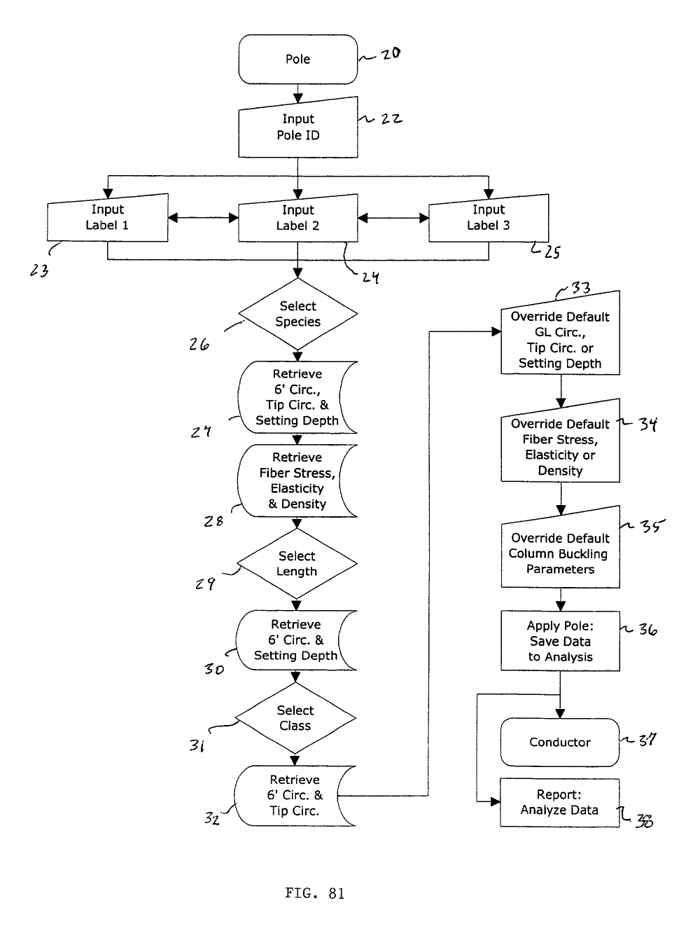

The operation of the software in FIG. 64 ends with the pole 20 start end process terminal. The software operation then flows to the pole in FIG. 81, FIG. 81 showing the software operations corresponding to the screen display of FIG. 65. The pole terminal 20 flows to the manually inputted pole identification 22, label 1, label 2, and label 3 for the poles, as shown by reference numbers 23-25. A decision is made with respect to the species 26, length 29, and class 31 of tree selected. Data is retrieved from databanks indicated by reference numbers 27, 28, 30, and 32. As shown by reference numbers 33-35, the default setting may be manually overridden. The software then operates to save the analysis created thus far 36, and allows the user to move to the next data input page for conductors 37, or to process or analyze data 38 for the summary report.

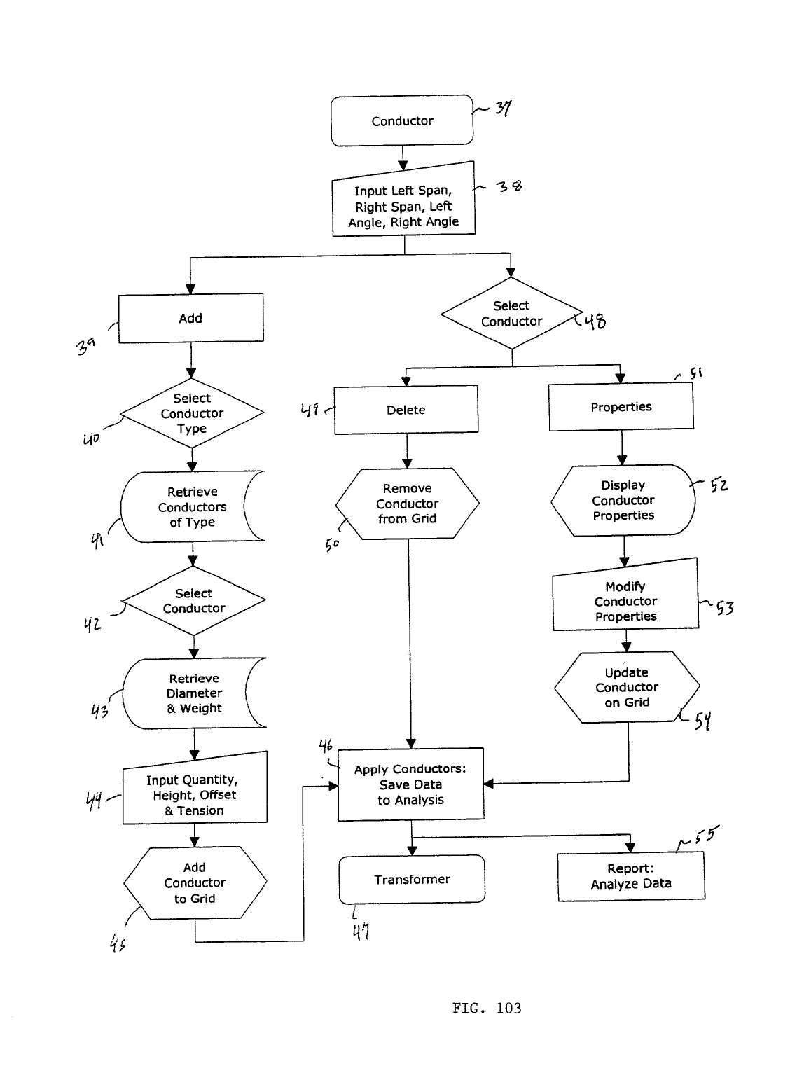

In FIG. 103, the conductor terminal 37 starts the process for the operation of the software with respect to the conductor data, the data input page for this operation seen in FIG. 66. The operation to add a conductor 39 begins with selecting a conductor type 40, and retrieving from databases conductor types and weights as indicated by reference numbers 40-43. Manual inputs are indicated by reference number 44, and the data is prepared and modified 45 and added to the grid and saved 46. The software may also operate as indicated by reference numbers 48-54, such that they may be removed from the grid 50 or updated 54. The software then operates to pull up the transformer 47 page or to generate an analysis report 55 wherein the pole loading is calculated.

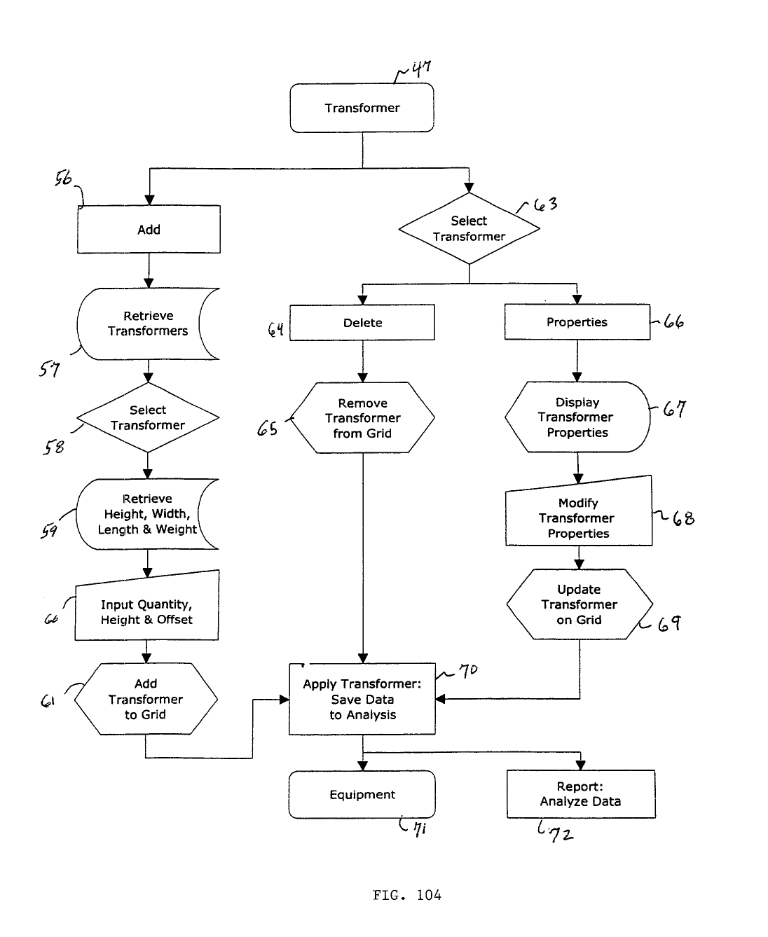

The flowcharts and symbols seen in FIGS. 104-106 are similar to the flowchart seen in FIG. 103, as seen in those figures. FIGS. 104-106 correspond to FIGS. 72, 74, and 76, the data input pages for transformers, equipment and guy wire respectively. The figures represented by reference numbers 56-61 in FIG. 104 indicate the adding of a transformer to the database. The figures represented by reference numbers 63-69 indicate the operation of deleting or modifying transformer properties. The reference numbers 70 and 72 analyze data and calculate loading for use in the summary report. Reference number 71 operates to bring up the equipment page.

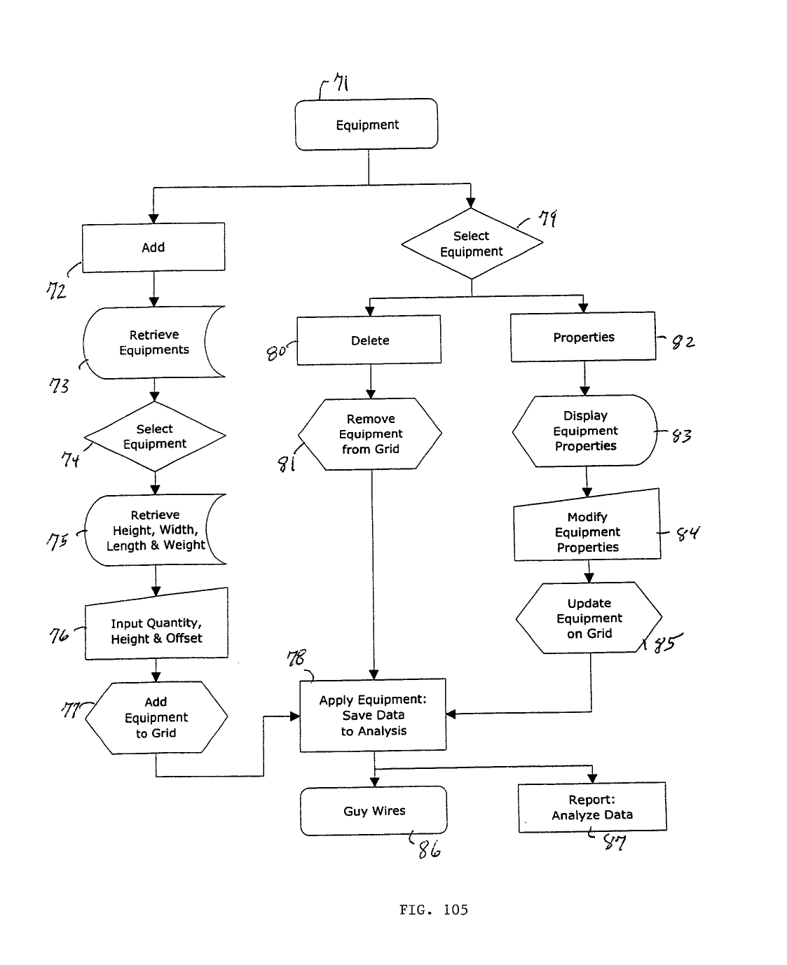

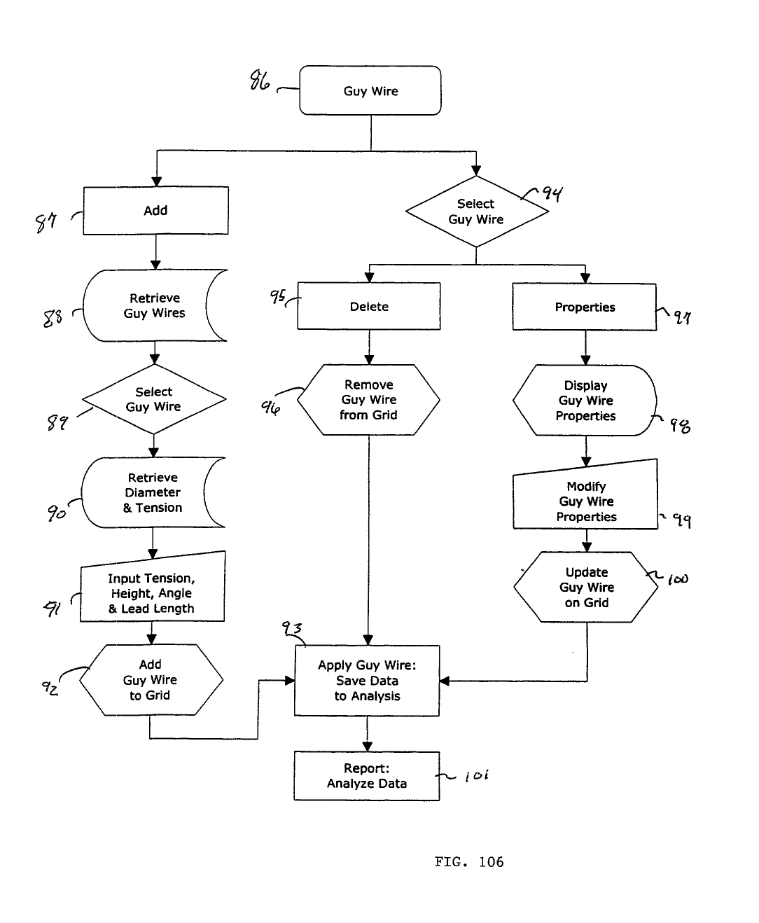

The figures represented by reference numbers 72-77 in FIG. 105 indicate the adding of equipment to the database. The figures represented by reference numbers 79-85 indicate the operation of deleting or modifying equipment properties. The reference numbers 78 and 87 analyze the data and calculate loading. Reference number 86 operates to bring up the guy wire page (FIG. 106).

The figures represented by reference numbers 87 to 92 in FIG. 106 indicate the adding of guy wires to the database. The figures represented by reference numbers 94 to 100 indicate the operation of deleting or modifying properties of the guy wires. The reference number indicated by 93 serves to save the guy wire data to the pole analysis. In the figure indicated by reference number 101, guy wire data is analyzed and loading is calculated and reported.

It is understood that the user may select any of the data input pages (FIGS. 48, 65, 66, 72, 74, and 76) and the computer program will operated in accordance with the flowcharts described above. This illustrates the versatility of the computer program as the user is able to go to any data input page at any time and change or modify data. A new summary report with associated graphs are automatically generated by the computer program being executed on the computer.

It is understood that while the invention has been described in detail herein, the invention can be otherwise embodied without departing from the principles thereof. All of these other embodiments are meant to come within the scope of the present system, methodology, and computer program product for determining the loading on a pole as defined by the claims.

1. In a computer having a display device, an entry device, and a computer processor for executing a computer program, a method of pole loading analysis comprising the steps of:
providing a computer executable program;
running the computer executable program on the computer;
inputting data pertaining to pole loading into the computer;
determining the loading on a pole; and
outputting at least one result to an output means.

2. The method of claim 1, further comprising the step of selecting pole loading code standards for the pole loading analysis from a database having the pole loading code standards stored therein.

3. The method of claim 2 wherein the code loading standards are selected from the database storing at least one of the following: the National Electrical Safety Code standards; the alternative national electric code standards; and the California General Order No. 95 pole loading standards.

4. The method of claim 1 wherein the computer executable program automatically causes the step of determining the loading on the pole to be updated when data is input into the computer.

5. The method of claim 1, wherein the step of providing a computer executable program comprises providing the computer executable program in the form of a computer program product.

6. The method of claim 1 wherein the input pole loading data includes loads placed on the pole from at least one of the following: power conductors; communications cables; fiber optic cables; the pole itself; transformers; equipment; guy wires; ice; and wind.

7. The method of claim 1 wherein the step of determining the loading on the pole determines the transverse loading on the pole and determines the vertical loading on the pole.

8. The method of claim 7 wherein the step of determining the transverse loading on the pole further determines the percentage of the pole capacity utilized due to the transverse loading and determines the percentage of transverse load capacity remaining, and the step of determining the vertical loading on the pole further determines the percentage of pole capacity utilized due to the vertical loading and determines the percentage of vertical pole capacity remaining.

9. The method of claim 1 wherein the step of inputting data pertaining to pole loading is accomplished by way of inputting data into a plurality of data input pages generated by the computer executable program being run on the computer.

10. The method of claim 9 wherein the plurality of data input pages includes at least one of the following data input pages: a general data input page having a wind data input field and a ice data input field; a pole data input page; a conductor data input page; a transformer data input page; an equipment data input page; and a guy wire data input page.

11. The method of claim 10 further comprising the step of maintaining a real time tally window having pull down menus for allowing the user to have access to the inputted data for each data input page, and for allowing the user access to the other data input pages.

12. The method of claim 11 wherein the step of maintaining the real time tally includes keeping and updating a real time running tally of the percentage of pole capacity being utilized due to the loading imposed on the pole.

13. The method of claim 1 further comprising the step of conducting a computerized logic check for alerting the user to potential logical errors in inputted data, so that the error may be corrected before the analysis continues.

14. The method of claim 1 further comprising the step of creating a reference pole as a default configuration for poles having the same loading placed upon them, so that a user can quickly analyze poles by repeatedly using the reference pole as a starting point for a new pole analysis.

15. The method of claim 1 further comprising the step of conducting a what if scenario, for allowing data pertaining to a first pole to be saved, and then cloning this data and creating a cloned pole having the same data as the first pole, so that the loading on the cloned pole can be altered, without the first pole's data being altered.

16. The method of claim 1 wherein the output means is a computer screen display for displaying the results.

17. The method of claim 1 further comprising the step of outputting the at least one result in the form of at least one of the following: a printed report; an electronic report; a screen display; and an email.

18. The method of claim 1 wherein the step of outputting at least one result further comprises the step of outputting the results graphically in at least one of the following forms: pole height versus horizontal shear load as a line graph; pole height versus bending moment as a line graph; pole height versus compressive stress as a line graph; component moment as percentage of total moment as a pie chart; component moment as percentage of pole capacity at groundline as a bar chart; pole height versus pole deflection as a line graph.

19. A computer program product for use with a computer, the computer program product comprising:
a computer usable medium having computer readable program codes embodied in the medium, the computer readable codes for causing the computer to:
define fields for the input of pole data;
define fields for the input of pole loading data;
determine pole loading values from the inputted pole data and the inputted pole loading data; and
display at least one result generated from the determinations made from the pole loading values.

20. The computer program product of claim 19
wherein the field for the input of pole loading data further defines fields for at least one of the following data inputs: conductor loading data; communication cable loading data; transformer loading data; equipment loading data; guy wire loading data; ice loading data; wind loading data; and pole species data.

21. The computer program of claim 19, the computer codes for further causing the computer to generate at least one of the following: a running tally of the load; a tally window; a warning logic procedure; a related pole analysis procedure; a reference pole analysis procedure; a summary report output; and graphical outputs.

22. The computer program product of claim 19 wherein the computer usable medium is selected from the group including CD-ROM, floppy disk, hard drive, and optical disk.

23. The computer program product of claim 19, wherein the defined input fields for inputting information on pole characteristics are for providing dialog boxes that a user can use to input at least one of the following data inputs: an identification number of the pole, a related pole identification, the species of tree the pole is made of, the class of the pole, the length of the pole, the setting depth of the pole, modulus of rupture, the modulus of elasticity, the density of the pole, and the buckling height above ground level for the pole.

24. An article of manufacture comprising:
a computer usable medium having computer readable program codes embodied in the medium, the computer readable codes for causing the computer to:
define fields for an input of pole data;
define fields for an input of pole loading data;
determine pole loading values from the inputted pole data and the inputted pole loading data;
conduct a related analysis;
conduct a reference analysis;
alert of logic errors;
calculate pole loading from the inputted data;
display results generated from the pole loading calculations
saving the input pole data to the computer readable medium;
saving the results to the computer readable medium.

25. The article of manufacture of claim 24 wherein the computer readable codes for further causing the computer to store data input into the computer, the data including data pertaining to the pole, power conductors; communications cables; fiber optic cables; transformers; equipment; guy wires; ice; wind; and pole loading standards.

26. The article of manufacture of claim 25 wherein the computer readable codes cause the computer to generate computer at least one display screen having a graphical user interface so that the user may input pole loading data.

27. The article of manufacture of claim 26 wherein the screen displays further comprise a screen display for at least one of the following: general data input; pole data input; conductor data input; transformer data input; equipment data input; transformer data input; and guy wire data input.

28. The article of manufacture of claim 24 wherein the computer readable codes retrieve data input into the computer.

29. The article of manufacture of claim 24 wherein the computer readable codes for further causing the analyses generated computer readable codes to be displayed on a computer screen in the form of tables, graphs and charts.

30. The article of manufacture of claim 29 wherein the analyses generated are displayed on a computer screen in at least one of the following formats: pole height versus horizontal shear load, pole height versus bending moment, pole height versus compressive stress, pole height versus deflection, a pie chart showing component moments as a percentage of the total moment, a bar graph showing component moments as a percentage of pole capacity at groundline.

31. The article of manufacture of claim 26 wherein the article is manufactured in one of the following form selected from the group comprising CD-ROM, floppy disk, optical disk, and carrier wave transmission.

32. The article of manufacture of claim 24 wherein the computer readable codes are for causing the computer to display a running tally of the percentage of the pole capacity utilized due to the input pole loading data.

33. The article of manufacture of claim 24 wherein the computer readable codes are for further causing tally window to be displayed on the computer screen that shows a tally of the loading on the pole.

34. The article of manufacture of claim 24 wherein the computer readable codes are for causing the computer to conduct reference analyses for using the same data for poles having the same specifications.

35. The article of manufacture of claim 24 wherein the computer readable codes are for causing the computer to conduct related analyses to determine what if scenarios, wherein different pole loadings may be inputted for a pole, with out altering the poles original data.

36. The article of manufacture of claim 24 for wherein the computer readable codes are for causing the computer to generate an output report from the input data displaying the percentage of pole capacity utilized due to the loading.

37. A system for determining loading on a pole comprising:
a computer processor;
a memory for storing input pole data and for storing input pole loading data;
computer executable instructions capable of being executed on the computer processor, the computer executable instructions for calculating the loading on the pole from the input pole data and the input pole loading data stored in the memory; and
a means for outputting at least one result generated by the computer executable instructions when executed on the computer processor.

38. The system of claim 37 wherein the data stored in the memory is at least one of the following: general data input; pole data input; conductor data input; transformer data input; equipment data input; transformer data input; and guy wire data input.

39. The system of claim 37 wherein the pole loading data is updated in real time.

40. The system of claim 37 further having at least one of the following computerized features: tally of pole loading; running tally of pole loading; warning logic; related analysis; reference analysis.

41. The system of claim 40 wherein the warning logic alerts that a piece of input data should be checked for accuracy.

42. The system of claim 37 further wherein the computer executable instructions generate a plurality of data input pages, including at least one of the following: a general data input page; a pole data input page; a conductor data input page; a transformer data input page; an equipment data input page; a transformer data input page; and a guy wire data input page.

43. The system of claim 37 wherein the means for outputting the results generated by the computer executable instructions is a computer screen display, and wherein the output results include a summary report of the loading on the pole.

44. The system of claim 41 wherein the results are graphical displays showing at least one of the following: pole height versus horizontal shear load; pole height versus bending moment; pole height versus compressive stress; pole height versus deflection; a pie chart showing component moments as a percentage of the total moment; and a bar graph showing component moments as a percentage of pole capacity at groundline.

45. The system of claim 44 wherein the memory stores the output results.

46. The system of claim 37 further wherein the computer executable instructions generate related analyses for conducting what if type scenarios with respect to pole loading, and further generate reference analyses for allowing reference poles to be generated and then used in subsequent analyses.

47. A memory for storing data for access by an application program being executed on a data processing system, comprising:
a data structure in operative association with the memory for storing and organizing data pertaining to pole loading, the data for being manipulated by the application program when the application program is executed on the computer, wherein the data the stored in the memory includes data for pole loading code standards, transverse pole loading data, vertical pole loading data, and pole characteristic data.

48. The memory according to claim 47 wherein the data structure further stores and organizes output result data generated by the application program being executed on the data processing system, and stores and organizes the output results data, so that the output results may then be displayed on display devices.

49. The memory according to claim 48 wherein the data structure further stores and organizes at the data for at least one of the following: general data inputs; pole data inputs; conductor data inputs; transformer data inputs; equipment data inputs; transformer data inputs; and guy wire data inputs; and equipment data inputs.

50. The memory according to claim 49 wherein the data structure further stores and organizes graphical data for at least one of the following: pole height versus horizontal shear load; pole height versus bending moment; pole height versus compressive stress; pole height versus deflection; a pie chart showing component moments as a percentage of the total moment; and a bar graph showing component moments as a percentage of pole capacity at groundline.

51. An method determining the loading on a pole comprising the operations of:
providing a computer processor;
providing a computer executable program for running on the computer processor, the program for generating a computer screen display with a graphical user interface capability, and a for generating a plurality of data input fields;
inputting data into the data input fields by way of the computer screen display;
automatically updating the computer screen display to reflect the input data;
determining transverse loading and vertical loading on the pole with respect to the input data; and
outputting a result to the computer screen display.

52. The method of claim 51 further comprising the operations of:
providing a computerized screen editor display;
providing a data input page for at least one of the following: a general data input page; a pole data input page; a conductor data input page; a transformer data input page; an equipment data input page; and a guy wire data input page;
allowing a user to enter and modify the data in any of the by selecting different data input pages at any time;
saving the modified data entered in the data input pages;
determining the pole loading using the modified data; and
outputting the result to a summary report.

53. The method of claim 52 wherein the summary report is at least a one page one page document.

54. A computer software program for being executed on a computer processor, the program for determining the loading on a pole, the program having a database for storing data, the database for storing data pertaining to at least one of the following: default safety codes; default construction grades; and default loading districts, such that a user has access to the data in the database.

55. The program of claim 54, wherein the user of the program selects one or more of the following: a value to be used for a transverse wind overload factor, a value to be used for a transverse wire overload factor, a value to be used for a vertical overload factor, a value to be used for ice radial thickness, a value to be used for a wind pressure; and a value to be used for wind speed, the values for being used in determining the loading on the pole.
